(19) United States
(12) Patent Application Publication
(10) Pub. No.: US 2021/0265374 A1
(43) Pub. Date: Aug. 26, 2021

(54) SEMICONDUCTOR MEMORY DEVICE

(71) Applicant: Kioxia Corporation, Tokyo (JP)

(72) Inventor: Taichi IWASAKI, Yokkaichi (JP)

(73) Assignee: Kioxia Corporation, Tokyo (JP)

(21) Appl. No.: 17/119,122

(22) Filed: Dec. 11, 2020

(30) Foreign Application Priority Data
Feb. 21, 2020 (JP) 2020-028746

(51) Int. Cl. H01L 27/11556; H01L 27/11582; G11C 5/06; G11C 5/02; H01L 23/532

(52) U.S. Cl. CPC H01L 27/11556; H01L 27/11582; H01L 23/53271; G11C 5/025; H01L 23/53209; G11C 5/06

(57) ABSTRACT

A semiconductor memory device includes: a plurality of first conductive layers disposed to be mutually separated; a second conductive layer disposed to be separated from the plurality of first conductive layers; a semiconductor layer integrally formed; agate insulating layer; a plurality of first insulating portions separating the plurality of first conductive layers and the second conductive layer; and a plurality of second insulating portions, at least one second insulating portion separating the second conductive layer into two or more between the first insulating portions mutually adjacent. The plurality of first conductive layers are each continuously formed between the first insulating portions mutually adjacent, and the plurality of first conductive layers contain a first material. The second conductive layer contains a second material different from the first material.

### CROSS-REFERENCE TO RELATED APPLICATIONS

This application is based upon and claims the benefit of Japanese Patent Application No. 2020-028746, filed on Feb. 21, 2020, the entire contents of which are incorporated herein by reference.

### BACKGROUND

### Field

Embodiments described herein relate generally to a semiconductor memory device.

### Description of the Related Art

There has been known a semiconductor memory device that includes a substrate, a plurality of conductive layers, a semiconductor layer, and a gate insulating layer. The plurality of conductive layers are disposed in a first direction intersecting with a surface of the substrate, and extend in a second direction intersecting with the first direction. The semiconductor layer extends in the first direction, and is opposed to the plurality of conductive layers. The gate insulating layer is disposed between the plurality of conductive layers and the semiconductor layer.

### BRIEF DESCRIPTION OF THE DRAWINGS

FIG. 1 is a schematic block diagram illustrating a configuration of a semiconductor memory device according to a first embodiment;

FIG. 2 is a schematic block diagram illustrating the exemplary configuration;

FIG. 3 is a schematic circuit diagram illustrating the exemplary configuration;

FIG. 4 is a schematic plan view illustrating the exemplary configuration;

FIG. 5 is a schematic perspective view of apart indicated as A in FIG. 4;

FIG. 6 is a schematic cross-sectional view of a part indicated as C in FIG. 5;

FIG. 7 is a schematic plan view of a part indicated as B in FIG. 4;

FIG. 8 is a schematic cross-sectional view of the structure illustrated in FIG. 7 taken along a line A-A′;

FIG. 9 is a schematic cross-sectional view illustrating a method for manufacturing the semiconductor memory device;

FIG. 10 is a schematic cross-sectional view illustrating the manufacturing method;

FIG. 11 is a schematic cross-sectional view illustrating the manufacturing method;

FIG. 12 is a schematic cross-sectional view illustrating the manufacturing method;

FIG. 13 is a schematic cross-sectional view illustrating the manufacturing method;

FIG. 14 is a schematic cross-sectional view illustrating the manufacturing method;

FIG. 15 is a schematic cross-sectional view illustrating the manufacturing method;

FIG. 16 is a schematic cross-sectional view illustrating the manufacturing method;

FIG. 17 is a schematic cross-sectional view illustrating the manufacturing method;

FIG. 18 is a schematic cross-sectional view illustrating the manufacturing method;

FIG. 19 is a schematic cross-sectional view illustrating the manufacturing method;

FIG. 20 is a schematic cross-sectional view illustrating the manufacturing method;

FIG. 21 is a schematic cross-sectional view illustrating the manufacturing method;

FIG. 22 is a schematic cross-sectional view illustrating the manufacturing method;

FIG. 23A is a schematic cross-sectional view illustrating a method for manufacturing a semiconductor memory device according to a comparative example 1;

FIG. 23B is a schematic cross-sectional view illustrating the method for manufacturing the semiconductor memory device;

FIG. 23C is a schematic cross-sectional view illustrating a method for manufacturing a semiconductor memory device according to a comparative example 2;

FIG. 24 is a schematic cross-sectional view of a semiconductor memory device according to a modification;

FIG. 25 is a schematic cross-sectional view illustrating an exemplary configuration of a semiconductor memory device according to a second embodiment;

FIG. 26 is a schematic cross-sectional view of a part indicated as D in FIG. 25;

FIG. 27 is a schematic cross-sectional view illustrating a method for manufacturing the semiconductor memory device;

FIG. 28 is a schematic cross-sectional view illustrating the manufacturing method;

FIG. 29 is a schematic cross-sectional view illustrating the manufacturing method;

FIG. 30 is a schematic cross-sectional view illustrating the manufacturing method;

FIG. 31 is a schematic cross-sectional view illustrating the manufacturing method;

FIG. 32 is a schematic cross-sectional view illustrating the manufacturing method;

FIG. 33 is a schematic cross-sectional view illustrating the manufacturing method;

FIG. 34 is a schematic cross-sectional view illustrating the manufacturing method;

FIG. 35 is a schematic cross-sectional view illustrating the manufacturing method;

FIG. 36 is a schematic cross-sectional view illustrating the manufacturing method;

FIG. 37 is a schematic cross-sectional view illustrating the manufacturing method;

FIG. 38 is a schematic cross-sectional view illustrating the manufacturing method;

FIG. 39 is a schematic cross-sectional view illustrating the manufacturing method;

FIG. 40 is a schematic cross-sectional view illustrating the manufacturing method; and

FIG. 41 is a schematic cross-sectional view illustrating the manufacturing method.

### DETAILED DESCRIPTION

A semiconductor memory device according to one embodiment includes: a plurality of first conductive layers disposed to be mutually separated in a first direction, the plurality of first conductive layers extending in a second direction intersecting with the first direction; a second conductive layer disposed to be separated from the plurality of first conductive layers in the first direction, the second conductive layer extending in the second direction; a semiconductor layer that extends in the first direction, the semiconductor layer being integrally formed in the first direction and being opposed to the plurality of first conductive layers and the second conductive layer; a gate insulating layer disposed between the plurality of first conductive layers and the semiconductor layer and between the second conductive layer and the semiconductor layer; a plurality of first insulating portions that extend in the first direction and the second direction in the plurality of first conductive layers and the second conductive layer, the plurality of first insulating portions separating the plurality of first conductive layers and the second conductive layer in a third direction intersecting with the first direction and the second direction; and a plurality of second insulating portions that extend in the first direction and the second direction in the second conductive layer, at least one second insulating portion of the plurality of second insulating portions being disposed between first insulating portions of the plurality of first insulating portions mutually adjacent in the third direction, the at least one second insulating portion separating the second conductive layer in the third direction into two or more between the first insulating portions mutually adjacent in the third direction. The plurality of first conductive layers are each continuously formed between the first insulating portions mutually adjacent in the third direction, and the plurality of first conductive layers contain a first material. The second conductive layer contains a second material different from the first material.

Next, the semiconductor memory device according to embodiments are described in detail with reference to the drawings. The following embodiments are only examples, and not described for the purpose of limiting the present invention. The following drawings are schematic, and for convenience of description, a part of a configuration and the like is sometimes omitted. Parts common in a plurality of embodiments are attached by same reference numerals and their descriptions may be omitted.

In this specification, when referring to “semiconductor memory device,” it may mean a memory die and may mean a memory system including a control die, such as a memory chip, a memory card, and an SSD. Further, it may mean a configuration including a host computer, such as a smartphone, a tablet terminal, and a personal computer.

In this specification, when referring to that a first configuration “is electrically connected” to a second configuration, the first configuration may be directly connected to the second configuration, and the first configuration may be connected to the second configuration via a wiring, a semiconductor member, a transistor, or the like. For example, when three transistors are connected in series, even when the second transistor is in OFF state, the first transistor is “electrically connected” to the third transistor.

In this specification, when referring to that a circuit or the like “electrically conducts” two wirings or the like, it may mean, for example, that this circuit or the like includes a transistor or the like, this transistor or the like is disposed on a current path between the two wirings, and this transistor or the like turns ON.

In this specification, a direction parallel to an upper surface of the substrate is referred to as an X-direction, a direction parallel to the upper surface of the substrate and perpendicular to the X-direction is referred to as a Y-direction, and a direction perpendicular to the upper surface of the substrate is referred to as a Z-direction.

In this specification, a direction along a predetermined plane may be referred to as a first direction, a direction along this predetermined plane and intersecting with the first direction may be referred to as a second direction, and a direction intersecting with this predetermined plane may be referred to as a third direction. These first direction, second direction, and third direction may correspond to any of the X-direction, the Y-direction, and the Z-direction and need not to correspond to these directions.

Expressions, such as “above” and “below,” in this specification are based on the substrate. For example, a direction away from the substrate along the Z-direction is referred to as above and a direction approaching the substrate along the Z-direction is referred to as below. A lower surface and a lower end of a certain configuration mean a surface and an end portion at the substrate side of this configuration. An upper surface and an upper end of a certain configuration mean a surface and an end portion at a side opposite to the substrate of this configuration. A surface intersecting with the X-direction or the Y-direction is referred to as a side surface and the like.

In this specification, when referring to a “width” or a “thickness” in a predetermined direction of a configuration, a member, or the like, this may mean a width or a thickness in a cross-sectional surface or the like observed with a Scanning electron microscopy (SEM), a Transmission electron microscopy (TEM), or the like.

### First Embodiment

### Memory System 10

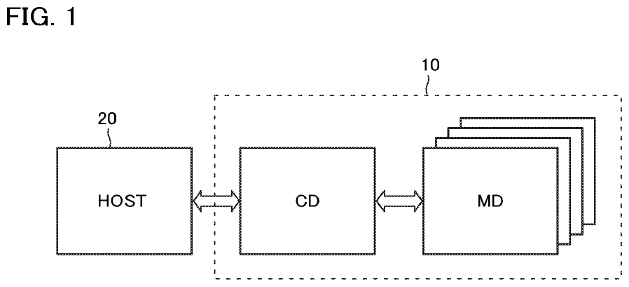

FIG. 1 is a schematic block diagram illustrating an exemplary configuration of a semiconductor memory device according to the first embodiment.

The memory system 10, for example, reads, writes, and erases user data in response to a signal transmitted from a host computer 20. The memory system 10 is, for example, any system that can store the user data including a memory chip, a memory card, and an SSD. The memory system 10 includes a plurality of memory dies MD that store the user data and a control die CD connected to the plurality of memory dies MD and the host computer 20. The control die CD includes, for example, a processor, a RAM, and the like, and performs conversion between a logical address and a physical address, bit error detection/correction, a garbage collection (compaction), a wear leveling, and the like.

### Configuration of Memory Die MD

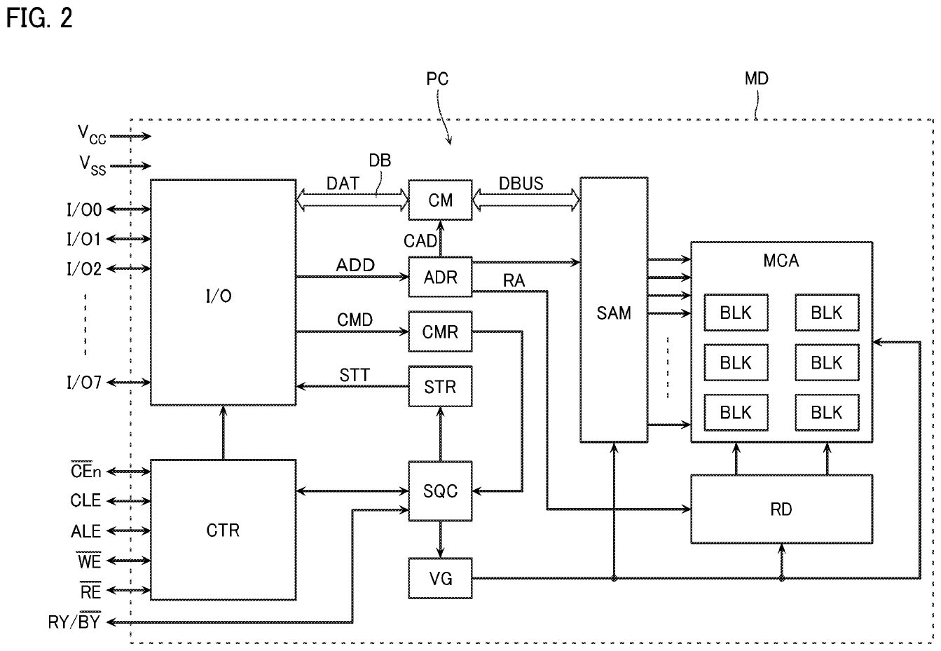

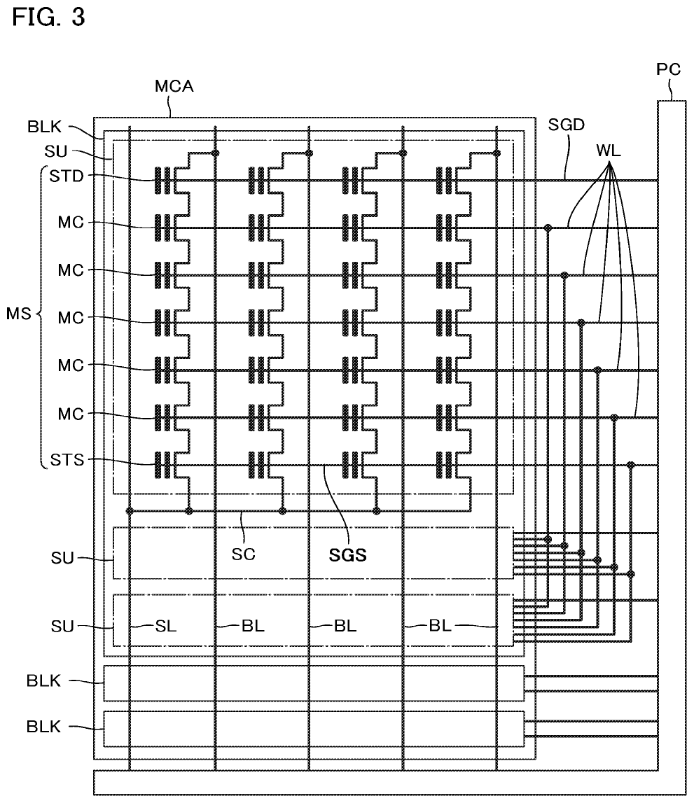

FIG. 2 and FIG. 3 are schematic block diagram and circuit diagram illustrating the exemplary configuration of the semiconductor memory device according to the embodiment.

As illustrated in FIG. 2, the memory die MD includes a memory cell array MCA that stores data and a peripheral circuit PC connected to the memory cell array MCA. The peripheral circuit PC includes a voltage generation circuit VG, a row decoder RD, a sense amplifier module SAM, and a sequencer SQC. The peripheral circuit PC includes a cache memory CM, an address register ADR, a command register CMR, and a status register STR. The peripheral circuit PC includes an input/output control circuit I/O and a logic circuit CTR.

The voltage generation circuit VG includes, for example, a step up circuit, such as a charge pump circuit, and a step down circuit, such as a regulator, and a plurality of voltage supply lines (not illustrated), which are connected to power supply terminals VCC, VSS. The voltage generation circuit VG generates a plurality of operating voltages applied to a bit line BL, a source line SL, a word line WL, and select gate lines (SGD, SGS) in a read operation, a write operation, and an erase operation on the memory cell array MCA, in accordance with an internal control signal from the sequencer SQC to simultaneously output the operating voltages from the plurality of voltage supply lines.

The row decoder RD includes, for example, a decode circuit and a switch circuit. The decode circuit decodes a row address RA held by the address register ADR. The switch circuit electrically conducts the word line WL and the select gate line (SGD, SGS) corresponding to the row address RA with corresponding voltage supply lines in accordance with an output signal of the decode circuit.

The sense amplifier module SAM includes a plurality of sense amplifier circuits corresponding to the plurality of bit lines BL, a plurality of voltage adjustment circuits, and a plurality of data latches. The sense amplifier circuit causes the data latch to latch data of “H” or “L” indicative of ON/OFF of the memory cell MC according to a current or a voltage of the bit line BL. The voltage adjustment circuit electrically conducts the bit line BL with the corresponding voltage supply line according to the data latched by the data latch.

The sense amplifier module SAM also includes a decode circuit and a switch circuit, which are not illustrated. The decode circuit decodes a column address CAD held in the address register ADR. The switch circuit electrically conducts the data latch corresponding to the column address CAD with a bus DB via a data bus DBUS and a cache memory CM in accordance with an output signal of the decode circuit.

The sequencer SQC sequentially decodes command data CMD held in the command register CMR and outputs an internal control signal to the row decoder RD, the sense amplifier module SAM, and the voltage generation circuit VG. The sequencer SQC outputs status data STT indicating its own status to the status register STR as necessary.

The sequencer SQC generates a ready/busy signal and outputs the ready/busy signal to a terminal RY//BY. In a period (busy period) in which the terminal RY//BY is an “L” state, the access to the memory die MD is basically inhibited. In a period (ready period) in which the terminal RY//BY is an “H” state, the access to the memory die MD is permitted.

The input/output control circuit I/O includes data input/output terminals I/O0 to I/O7, a shift register connected to these data input/output terminals I/O0 to I/O7, and a buffer memory connected to this shift register.

The buffer memory outputs data to the data latch in the sense amplifier module SAM, the address register ADR, or the command register CMR corresponding to the internal control signal from the logic circuit CTR. The buffer memory receives data from the data latch or the status register STR corresponding to the internal control signal from the logic circuit CTR. The buffer memory may be achieved by a part of the shift register, or may be achieved by a configuration, such as an SRAM.

The logic circuit CTR receives an external control signal from the control die CD via external control terminals /CEn, CLE, ALE, /WE, and /RE, and outputs the internal control signal to the input/output control circuit I/O corresponding the external control signal.

The memory cell array MCA includes a plurality of memory blocks BLK as illustrated in FIG. 3. The plurality of memory blocks BLK each include a plurality of string units SU. The plurality of string units SU each include a plurality of memory strings MS. The plurality of memory strings MS have one ends each connected to the peripheral circuit PC via a bit line BL. The plurality of memory strings MS have other ends each connected to the peripheral circuit PC via a common source line SL.

The memory string MS includes a drain-side select transistor STD, a plurality of memory cells MC (memory transistors), a source-side select transistor STS, which are connected in series between the bit line BL and the source line SL. Hereinafter, the drain-side select transistor STD and the source-side select transistor STS may be simply referred to as select transistors (STD, STS).

The memory cell MC is a field-effect type transistor including a semiconductor layer that functions as a channel region, a gate insulating film including an electric charge accumulating film, and a gate electrode. The memory cell MC has a threshold voltage that changes according to an electric charge amount in the electric charge accumulating film. The memory cell MC stores one bit or a plurality of bits of data. Word lines WL are connected to respective gate electrodes of the plurality of memory cells MC corresponding to one memory string MS. These word lines WL are each connected to all of the memory strings MS in one memory block BLK in common.

The select transistor (STD, STS) is a field-effect type transistor including a semiconductor layer that functions as a channel region, a gate insulating film, and a gate electrode. The select gate lines (SGD, SGS) are connected to the respective gate electrodes of the select transistors (STD, STS). The drain-side select gate line SGD is disposed corresponding to the string unit SU and connected to all of the memory strings MS in one string unit SU in common. The source-side select gate line SGS is connected to all of the memory strings MS in the plurality of string units SU in common.

### Structure of Memory Die MD

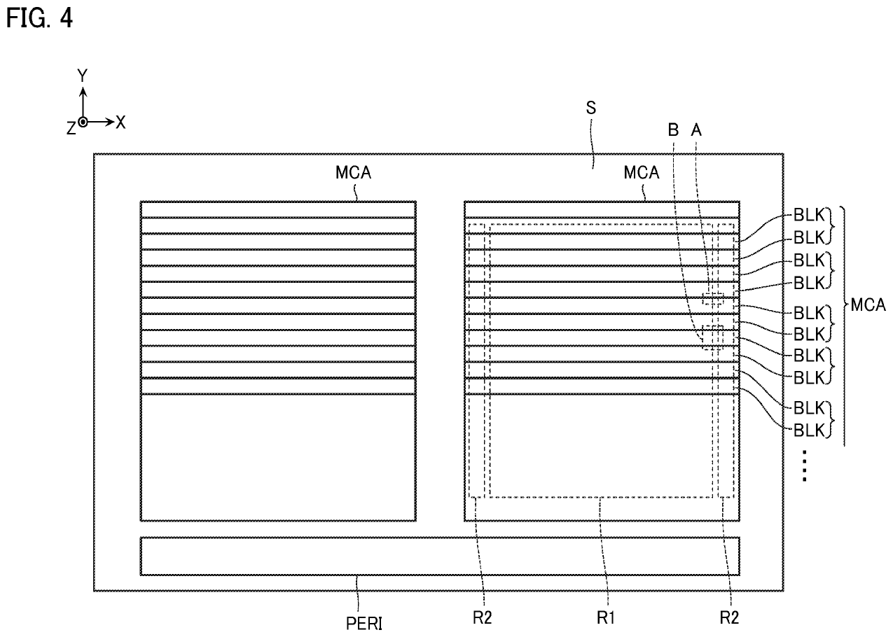

FIG. 4 is a schematic plan view illustrating an exemplary configuration of the semiconductor memory device according to the embodiment, and illustrates a planar structure of the memory die MD.

As illustrated in FIG. 4, on a substrate S, a plurality of memory cell arrays MCA and a region PERI are disposed. In the illustrated example, the two memory cell arrays MCA are disposed to be aligned in the X-direction on the substrate S, and the region PERI is disposed on one end in the Y-direction.

The memory cell array MCA includes a plurality of memory blocks BLK disposed in the Y-direction. The memory cell array MCA includes a region R1 in which the memory cells MC are disposed, and regions R2 in which contacts CC and the like are disposed in staircase patterns. The region PERI includes a part of the peripheral circuit PC, a pad electrode, and the like.

### Memory Cell Array MCA

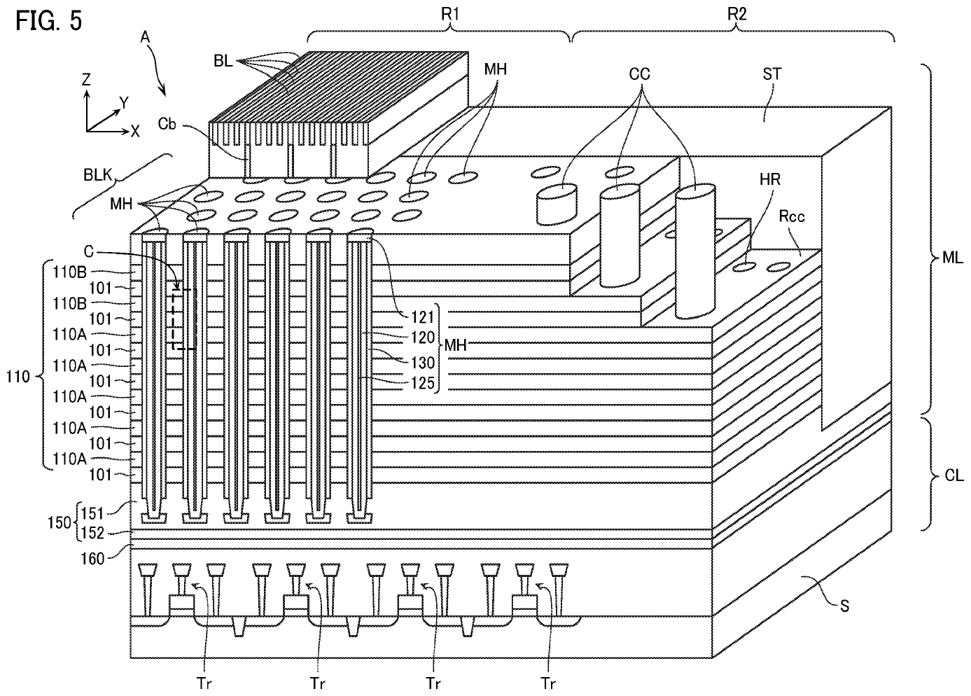

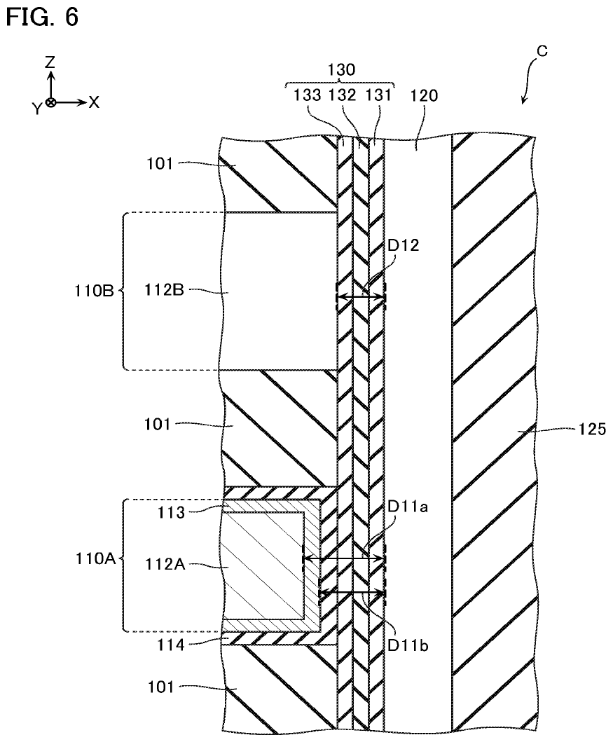

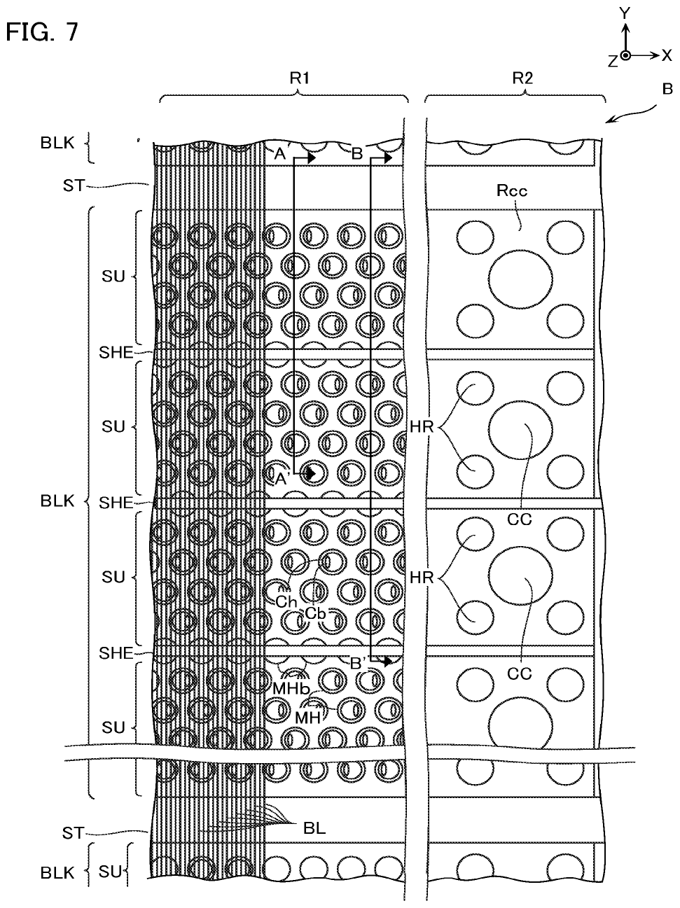

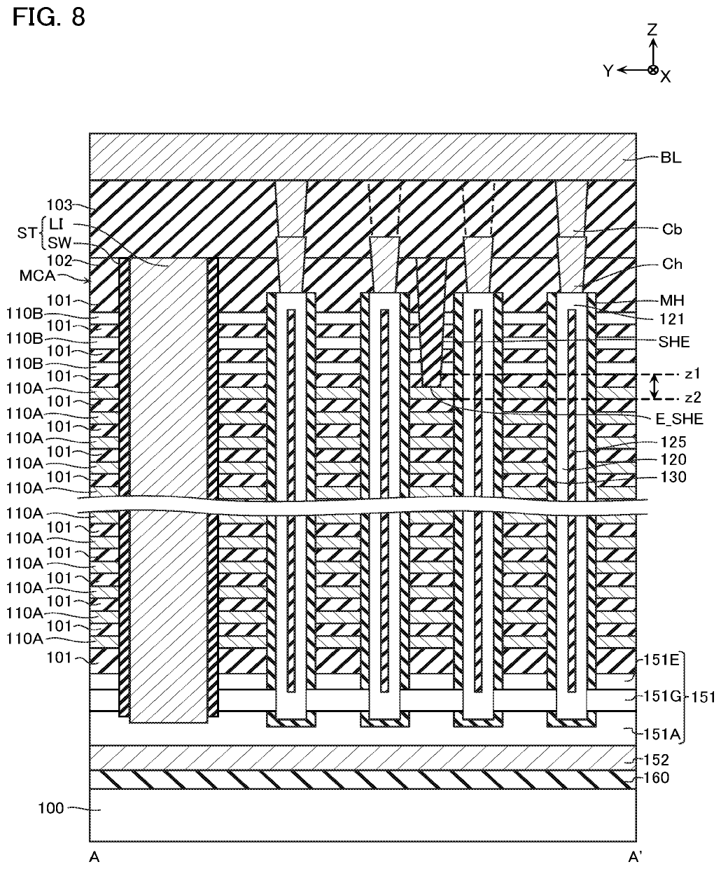

FIG. 5 is a schematic perspective view of a part indicated as A in FIG. 4. FIG. 6 is a schematic cross-sectional view of a part indicated as C in FIG. 5. FIG. 7 is a schematic plan view of a part indicated as B in FIG. 4, and partially illustrates the region R1 and the region R2 described above. FIG. 8 is a schematic cross-sectional view of the structure illustrated in FIG. 7 taken along a line A-A′ viewed in an arrow direction.

As illustrated in FIG. 5, the memory cell array MCA includes a memory layer ML and a circuit layer CL disposed below the memory layer ML.

### Memory Layer ML

In the memory layer ML, the memory block BLK includes, as illustrated in FIG. 5, a plurality of memory hole structures MH extending in the Z-direction, a plurality of conductive layers 110, a plurality of insulating layers 101, a plurality of bit lines BL, and a lower wiring layer 150. The plurality of conductive layers 110 include a plurality of conductive layers 110A and conductive layers 110B disposed in the Z-direction. The plurality of conductive layers 110 cover outer peripheral surfaces of the plurality of memory hole structures MH in an XY-cross-sectional surface. The plurality of insulating layers 101 are disposed between the plurality of conductive layers 110. The plurality of bit lines BL are connected to upper ends of the memory hole structures MH. The lower wiring layer 150 is connected to lower ends of the memory hole structures MH.

Between the two memory blocks BLK mutually adjacent in the Y-direction, for example, as illustrated in FIG. 5, an inter-block insulating layer ST is disposed. The inter-block insulating layer ST extends in the X-direction and the Z-direction in the plurality of conductive layers 110A and the plurality of conductive layers 110B, and separates the plurality of conductive layers 110A and the plurality of conductive layers 110B in the Y-direction.

The memory hole structures MH are disposed in the X-direction and the Y-direction in a predetermined pattern. The memory hole structure MH includes a semiconductor layer 120 extending in the Z-direction, a gate insulating layer 130 disposed between the semiconductor layer 120 and the conductive layers 110A and the conductive layers 110B, a semiconductor layer 121 connected to the upper end of the semiconductor layer 120, and an insulating layer 125 disposed in the center of the memory hole structure MH.

The semiconductor layer 120 functions as, for example, a channel region of the plurality of memory cells MC, the drain-side select transistor STD, and the source-side select transistor STS included in one memory string MS (FIG. 3). The semiconductor layer 120 has an approximately cylindrical shape integrally formed from the lower end to the upper end, and includes the insulating layer 125 of silicon oxide (SiO₂) or the like embedded in the center. The semiconductor layer 120 is, for example, a semiconductor layer of non-doped polycrystalline silicon (Si) or the like.

The gate insulating layer 130 extends in the Z-direction along an outer peripheral surface of the semiconductor layer 120, and has an approximately cylindrical shape integrally formed from the lower end to the upper end. As illustrated in FIG. 6, the gate insulating layer 130 includes a tunnel insulating layer 131, an electric charge accumulating layer 132, and a block insulating layer 133 which are stacked between the semiconductor layer 120 and conductive layers 110A and conductive layers 110B. The tunnel insulating layer 131 and the block insulating layer 133 are insulating layers of silicon oxide (SiO₂) or the like. The electric charge accumulating layer 132 is a layer of silicon nitride (SiN) or the like and can accumulate electric charge. The electric charge accumulating layer 132 may be a plurality of floating gates arranged in the Z-direction. This floating gate may contain polycrystalline silicon (Si) doped with N-type impurities, such as phosphorus (P), or P-type impurities, such as boron (B), non-doped polycrystalline silicon (Si), or the like.

The semiconductor layer 121 is a semiconductor layer of, for example, polycrystalline silicon (Si) containing N-type impurities, such as phosphorus (P).

The plurality of conductive layers 110A are disposed in the Z-direction via the insulating layers 101, and are conductive layers in approximately plate shapes extending in the X-direction and the Y-direction. As illustrated in FIG. 6, the conductive layer 110A includes a conductive film 112A and a barrier metal film 113 that covers an upper surface, a lower surface, and a side surface of this conductive film 112A. These upper surface, lower surface, and side surface of the barrier metal film 113 are covered with a high-dielectric insulating layer 114. The conductive film 112A is a metal film containing tungsten (W), molybdenum (Mo), or the like. The barrier metal film 113 is a metal film of titanium nitride (TiN) or the like. The high-dielectric insulating layer 114 is a metal oxide film of alumina (Al₂O₃) or the like.

The conductive layers 110A function as the word lines WL (FIG. 3) and the gate electrodes of the plurality of memory cells MC (FIG. 3) connected to the word lines WL.

One or a plurality of conductive layers 110B are disposed in the Z-direction via the insulating layers 101, and the conductive layer 110B is a conductive layer that extends in the X-direction and the Y-direction and has an approximately plate shape. As illustrated in FIG. 6, the conductive layer 110B includes a conductive film 112B. The conductive film 112B is a semiconductor film of polysilicon (Si) or the like.

The conductive layer 110B is disposed above the plurality of conductive layers 110A via the insulating layers 101, and functions as the drain-side select gate line SGD (FIG. 3) and the gate electrodes of the plurality of drain-side select transistors STD (FIG. 3) connected to this drain-side select gate line SGD.

As illustrated in FIG. 6, while the barrier metal film 113 and the high-dielectric insulating layer 114 are disposed between the conductive film 112A and the semiconductor layer 120, the barrier metal film 113 and the high-dielectric insulating layer 114 are not disposed between the conductive layer 110B and the semiconductor layer 120. Accordingly, a distance D11a between the conductive film 112A and the semiconductor layer 120 is greater than a distance D12 between the conductive layer 110B and the semiconductor layer 120 by a length corresponding to a total thickness of the barrier metal film 113 and the high-dielectric insulating layer 114. A distance D11b between the conductive layer 110A and the semiconductor layer 120 is greater than the distance D12 between the conductive layer 110B and the semiconductor layer 120 by a length corresponding to the thickness of the high-dielectric insulating layer 114.

A part of the conductive layers 110A disposed downward among the plurality of conductive layers 110A functions as the source-side select gate line SGS (FIG. 3) and the gate electrodes of the plurality of source-side select transistor STS (FIG. 3) connected thereto.

The insulating layers 101 are each disposed between the plurality of conductive layers 110A and the one or plurality of conductive layers 110B disposed in the Z-direction. The insulating layer 101 is an insulating film of silicon oxide (SiO₂) or the like.

The plurality of bit lines BL are disposed in the X-direction, and extend in the Y-direction. The bit lines BL are connected to the semiconductor layers 120 via contacts Cb and the semiconductor layers 121.

The lower wiring layer 150 includes, for example, as illustrated in FIG. 5, a conductive layer 151 connected to the semiconductor layers 120 and a conductive layer 152 disposed on a lower surface of the conductive layer 151. The lower wiring layer 150 functions as a lower wiring SC (FIG. 3).

The conductive layer 151 includes, for example, as illustrated in FIG. 8, a semiconductor layer 151E, a semiconductor layer 151G, and a semiconductor layer 151A. The semiconductor layer 151G is positioned below the semiconductor layer 151E and connected to parts of the side surfaces of the semiconductor layers 120 from the X-direction (FIG. 5) and the Y-direction. The semiconductor layer 151A is positioned below the semiconductor layer 151G. The semiconductor layer 151E, the semiconductor layer 151G, and the semiconductor layer 151A function as a part of the source line SL (FIG. 3). The semiconductor layer 151E, the semiconductor layer 151G, and the semiconductor layer 151A include conductive films of, for example, polycrystalline silicon containing impurities, such as phosphorus (P).

The conductive layer 152 is formed on a substrate 100 via an insulating layer 160, and includes a conductive film of, for example, metal, such as tungsten (W), polycrystalline silicon (Si) containing N-type impurities, such as phosphorus (P), or silicide. The insulating layer 160 is an insulating film of silicon oxide (SiO₂) or the like.

As illustrated in FIG. 7, in the region R1, a plurality of memory blocks BLK mutually adjacent in the Y-direction via the inter-block insulating layers ST are disposed. The memory blocks BLK each include a plurality of string units SU mutually adjacent in the Y-direction via insulating portions SHE. The insulating portion SHE includes a boundary surface with the string unit SU extending in the X-direction, and the boundary surface is disposed to extend approximately linearly in the X-direction. The insulating portion SHE has edge portions of its upper and lower ends approximately linearly extending in the X-direction. In each of the memory blocks BLK, a plurality of memory hole structures MH are disposed in a staggered pattern.

As illustrated in FIG. 7 and FIG. 8, the plurality of memory hole structures MH are disposed at positions separated from the insulating portions SHE in the X-direction and the Y-direction at predetermined intervals. The plurality of memory hole structures MH are electrically connected to mainly the bit lines BL via the contacts Ch and the contacts Cb. This memory hole structure MH functions as the memory string MS (FIG. 3).

As illustrated in FIG. 7, a plurality of memory hole structures MHb are disposed to be in contact with the insulating portions SHE in the X-direction at predetermined intervals. In the memory hole structure MHb, a groove is formed in an upper end portion of the semiconductor layer 120 and an upper end portion of the gate insulating layer 130, and the insulating portion SHE is disposed in the groove. This memory hole structure MHb is not electrically connected to the bit line BL, and does not function as the memory string MS. The memory hole structure MH may be disposed in a regular pattern in the X-direction and the Y-direction while omitting the memory hole structures MHb at the positions along the insulating portions SHE.

As illustrated in FIG. 8, a position of a lower end surface of the conductive layer 110B closest to the conductive layer 110A among the plurality of conductive layers 110B is defined as a position z1. A position of a lower end surface of the conductive layer 110A closest to the conductive layer 110B among the plurality of conductive layers 110A is defined as a position z2. A lower end portion ESHE in the Z-direction of the insulating portion SHE is disposed at a position below the position z1 including the position z1 and above the position z2 not including the position z2. For example, the lower end portion E SHE is disposed so as to be in contact with the conductive layer 110A closest to the conductive layer 110B among the plurality of conductive layers 110A. Since the insulating portion SHE is disposed at such a position, the insulating portion SHE separates the conductive layers 110B into two or more in the Y-direction but does not separate the conductive layers 110A between the inter-block insulating layers ST mutually adjacent in the Y-direction. In other words, the plurality of conductive layers 110A are continuously disposed between the inter-block insulating layers ST mutually adjacent in the Y-direction. At least one of the lower end portions E_SHE may be disposed so as to be in contact with the conductive layer 110A closest to the conductive layer 110B among the plurality of conductive layers 110A.

As illustrated in FIG. 8, the inter-block insulating layer ST includes an electrode portion LI and sidewall portions SW. The electrode portion LI functions as a connection electrode to the lower wiring layer 150. The sidewall portions SW function as regions that insulate between the electrode portion LI and the conductive layers 110A, the conductive layers 110B, and the like.

As illustrated in FIG. 5 and FIG. 7, contact regions Rcc are disposed in the region R2. For example, as illustrated in FIG. 5, the contact region Rcc includes the plurality of conductive layers 110A, the conductive layers 110B, the insulating layers 101, the contacts CC, and supporting structures HR. The contacts CC each extend in the Z-direction, and have respective lower ends connected to end portions in the X-direction of the plurality of conductive layers 110A and conductive layers 110B.

### Circuit Layer CL

For example, as illustrated in FIG. 5, the circuit layer CL includes the substrate S, a plurality of transistors Tr constituting the peripheral circuit PC, and a plurality of wirings and contacts connected to these plurality of transistors Tr.

The substrate S is a semiconductor substrate formed of single-crystal silicon (Si) or the like. The substrate S has a double well structure that includes, for example, an N-type impurity layer of phosphorus (P) or the like on a surface of a semiconductor substrate and further includes a P-type impurity layer of boron (B) or the like in this N-type impurity layer.

### Manufacturing Method

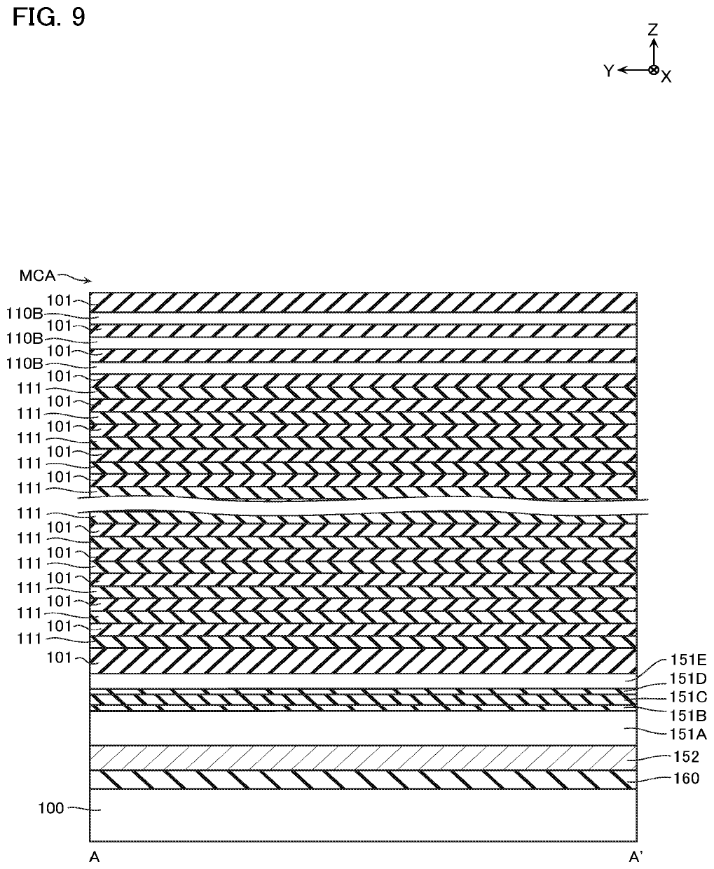

Next, with reference to FIG. 9 to FIG. 22, the method for manufacturing the semiconductor memory device according to the embodiment will be described. FIG. 9 to FIG. 22 illustrate cross-sectional surfaces taken along the line A-A′ in FIG. 7.

As illustrated in FIG. 9, in this manufacturing method, the insulating layer 160, the conductive layer 152, the semiconductor layer 151A, an insulating layer 151B, a sacrifice layer 151C, an insulating layer 151D, and the semiconductor layer 151E are formed on the substrate 100. The plurality of insulating layers 101 and sacrifice layers 111 as first films are alternately formed thereabove. The plurality of insulating layers 101 and the conductive layers 110B as second films are alternately formed thereabove.

The substrate 100 is, for example, a substrate that includes the circuit layer CL as illustrated in FIG. 5, or a semiconductor substrate of Si or the like. The insulating layer 160 is an insulating layer of silicon oxide or the like. The conductive layer 152 is a conductive film of tungsten silicide (WSi) or the like. The semiconductor layer 151A and the semiconductor layer 151E are semiconductor layers of, for example, polysilicon (Si) doped with phosphorus (P). The insulating layer 151B, the insulating layer 151D, and the insulating layer 101 are insulating layers of silicon oxide or the like. The sacrifice layer 151C and the sacrifice layer 111 are insulating layers of silicon nitride (SiN) or the like. The conductive layer 110B is a semiconductor layer of, for example, polysilicon (Si) doped with phosphorus (P). This process is performed by a method, such as Chemical Vapor Deposition (CVD).

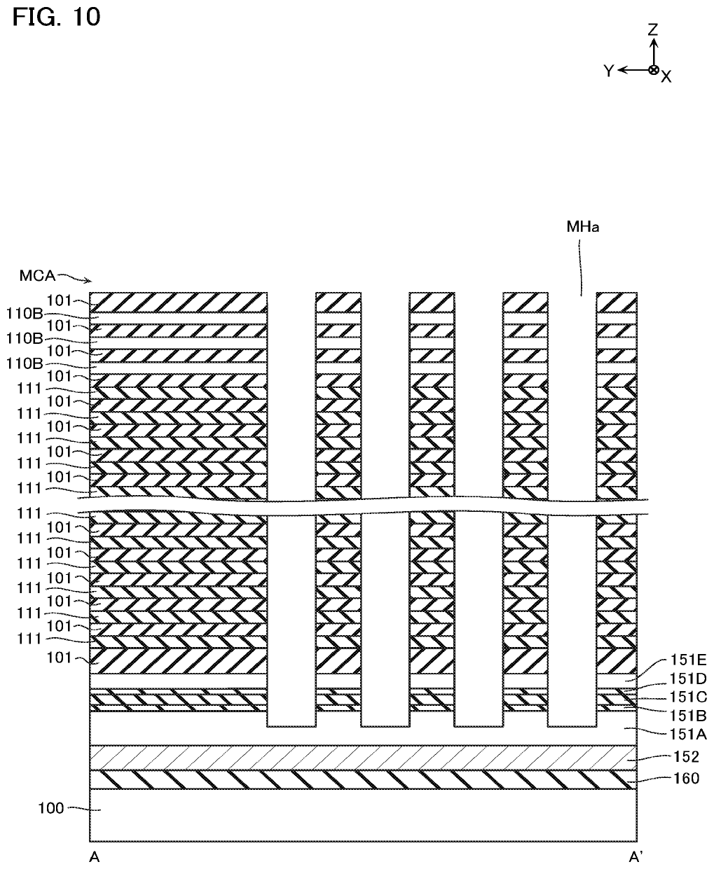

Next, as illustrated in FIG. 10, openings MHa are formed. The openings MHa extend in the Z-direction, and penetrate the insulating layers 101, the conductive layers 110B, the sacrifice layers 111, the semiconductor layer 151E, the insulating layer 151D, the sacrifice layer 151C, and the insulating layer 151B to expose the semiconductor layer 151A. In this process, for example, an insulating layer having openings at parts corresponding to the openings MHa is formed on an upper surface of the structure illustrated in FIG. 9, and Reactive Ion Etching (RIE) or the like is performed using the insulating layer as a mask, thus forming the openings MHa.

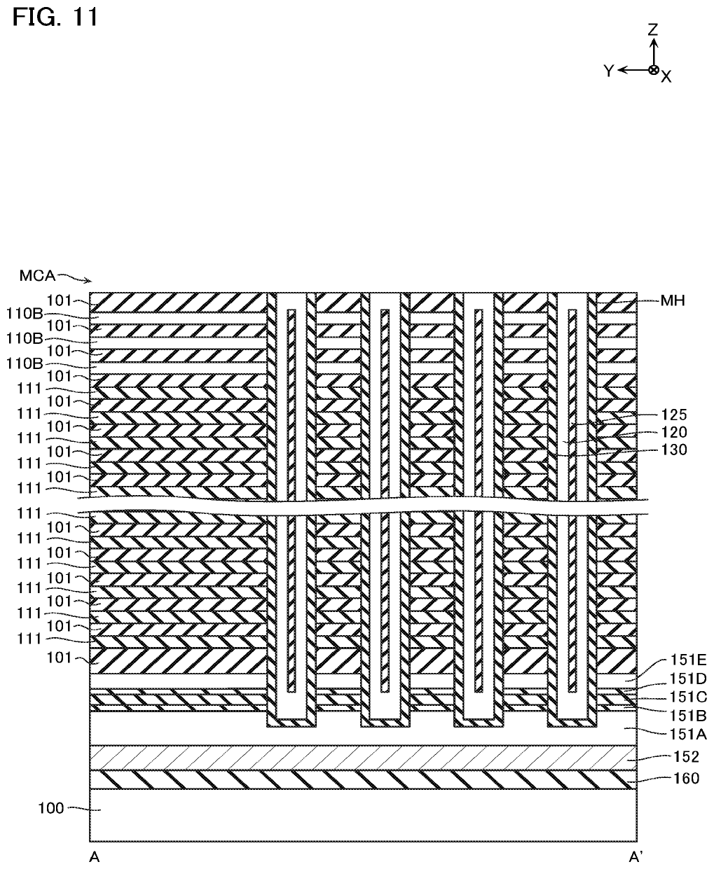

Next, as illustrated in FIG. 11, the gate insulating layers 130, the semiconductor layers 120, and the insulating layers 125 are formed on inner peripheral surfaces of the openings MHa. This process is performed by a method, such as CVD. Thus, the memory hole structures MH having approximately columnar shapes are formed. In this process, for example, a heat treatment to modify the crystalline structure of the semiconductor layers 120 is performed.

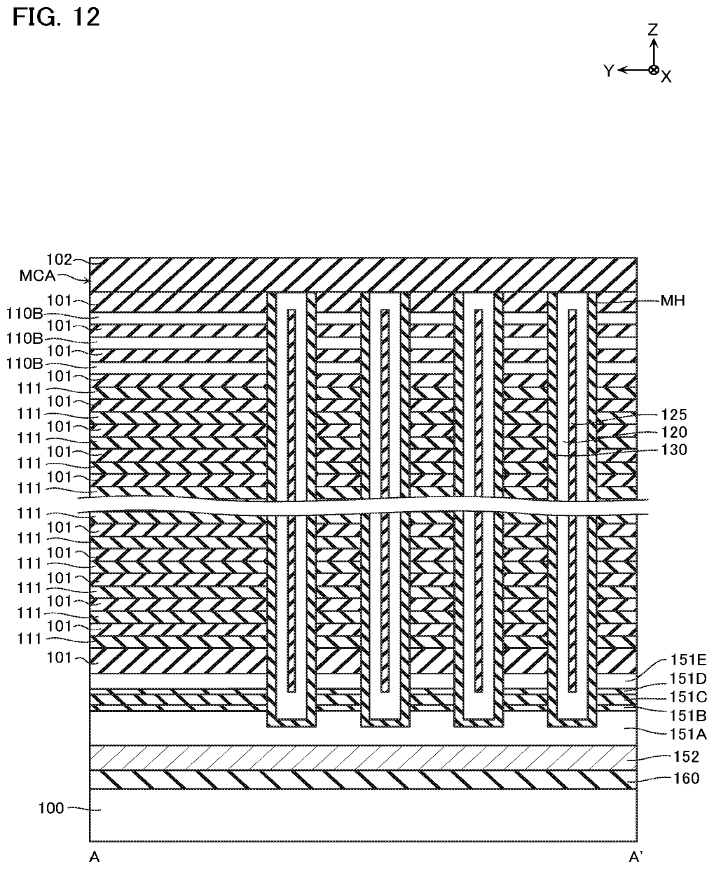

Next, as illustrated in FIG. 12, an insulating layer 102 of silicon oxide (SiO₂) or the like is formed on an upper surface of the structure illustrated in FIG. 11. This process is performed by a method, such as CVD.

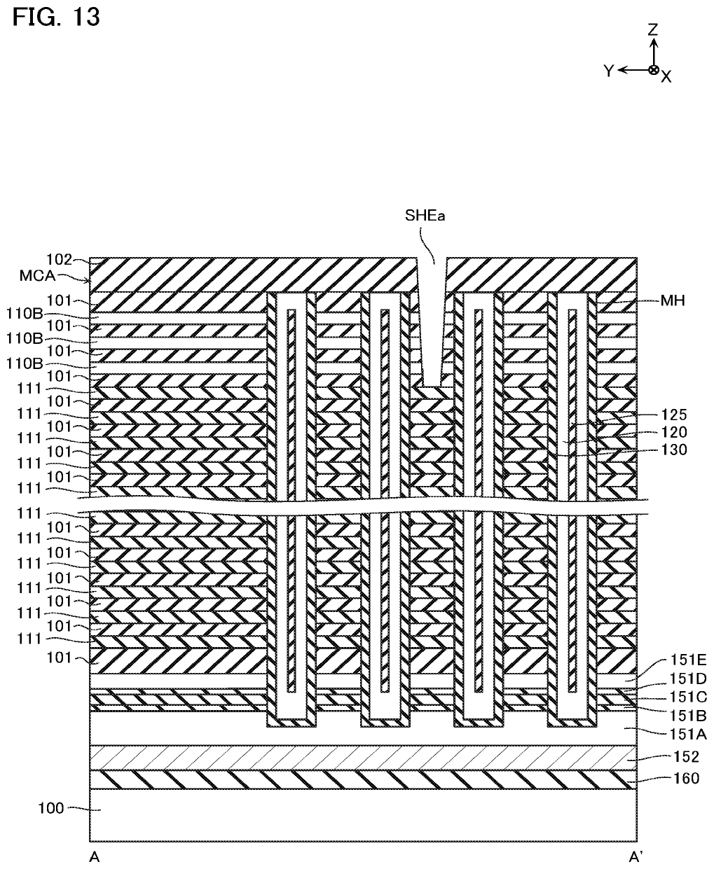

Next, as illustrated in FIG. 13, openings SHEa are formed. The openings SHEa extend in the X-direction and the Z-direction, and separate the plurality of conductive layers 110B in the Y-direction. The openings SHEa penetrate the insulating layer 102, the insulating layers 101, and the conductive layers 110B in the Z-direction to expose the uppermost layer of the plurality of sacrifice layers 111. This process is performed by a method, such as RIE.

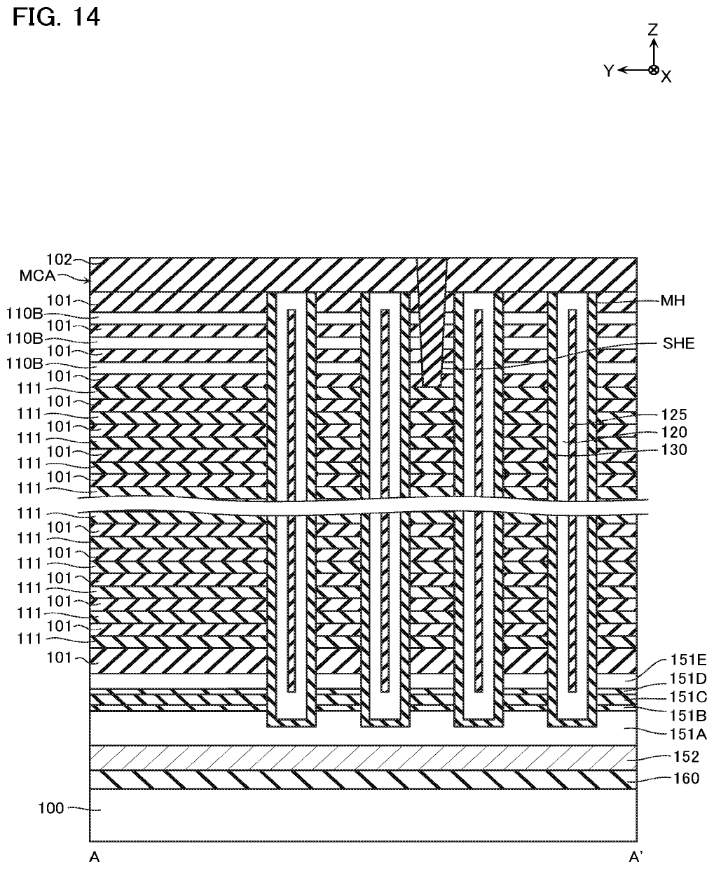

Next, as illustrated in FIG. 14, insulating layers of silicon oxide (SiO₂) or the like are embedded in the openings SHEa to form the insulating portions SHE. This process is performed by a method, such as CVD.

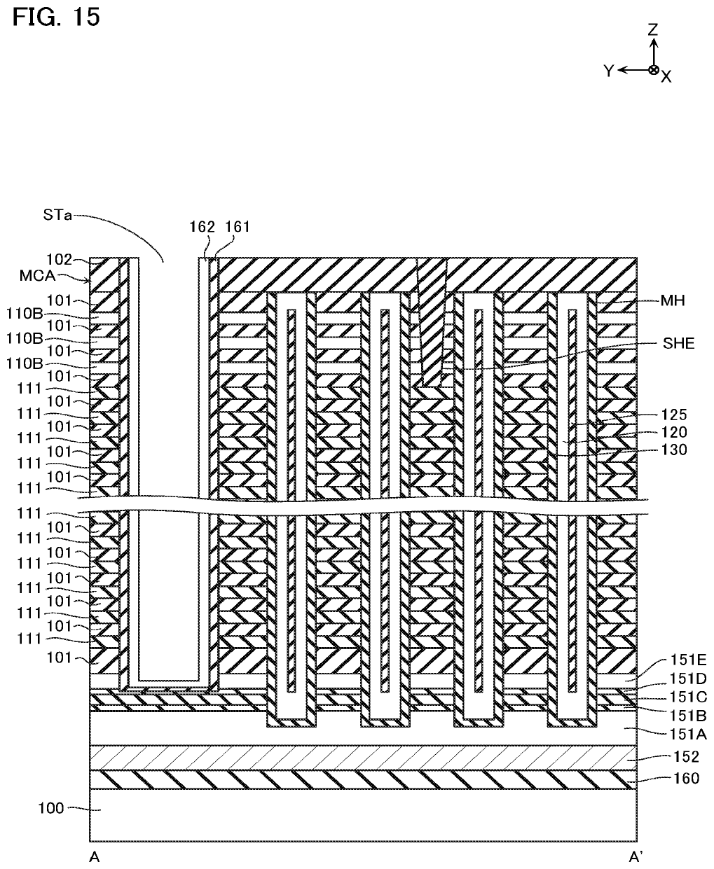

Next, as illustrated in FIG. 15, openings STa are formed. The opening STa extends in the X-direction and the Z-direction, and separates the plurality of conductive layers 110B and the plurality of sacrifice layers 111 in the Y-direction. The opening STa penetrates the insulating layer 102, the insulating layers 101, the conductive layers 110B, the sacrifice layers 111, and the semiconductor layer 151E in the Z-direction to expose the insulating layer 151D. This process is performed by a method, such as RIE.

As illustrated in FIG. 15, an insulating layer 161 of silicon oxide (SiO₂) or the like and a semiconductor layer 162 of amorphous silicon (Si) or the like are formed on an inner wall surface and a bottom surface of the opening STa. This process is performed by a method, such as CVD.

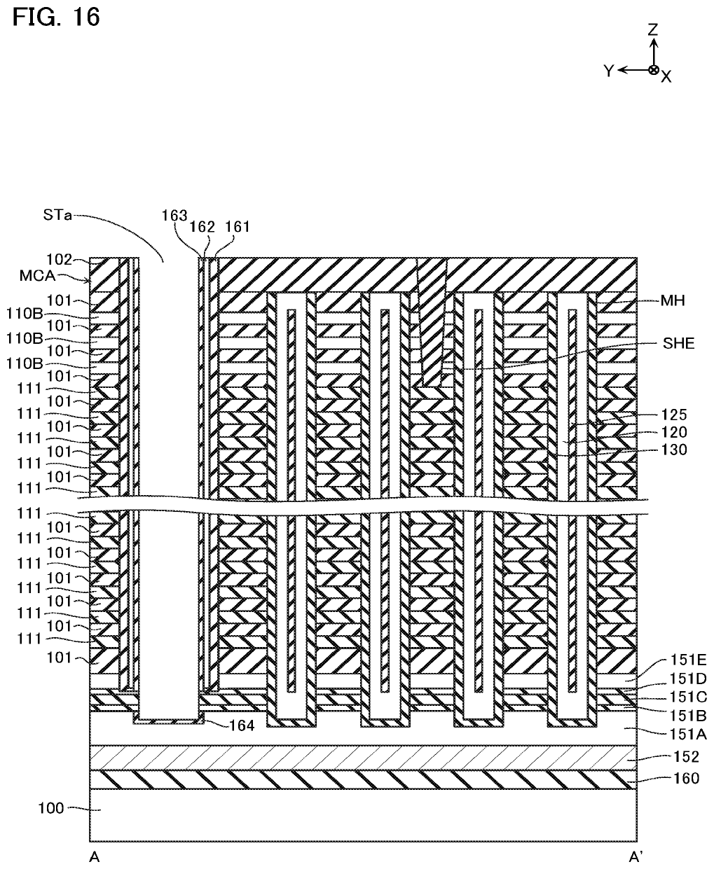

Next, as illustrated in FIG. 16, the bottom surfaces of the openings STa are dug down to the semiconductor layer 151A. This process is performed by a method, such as RIE. Next, in the inner wall surfaces of the openings STa, protective layers 163 are formed on exposed portions of the semiconductor layers 162, and protective layers 164 are formed on the bottom surfaces of the openings STa. The protective layer 163 and the protective layer 164 contain silicon oxide (SiO₂) or the like. This process is performed by a method, such as thermal oxidation.

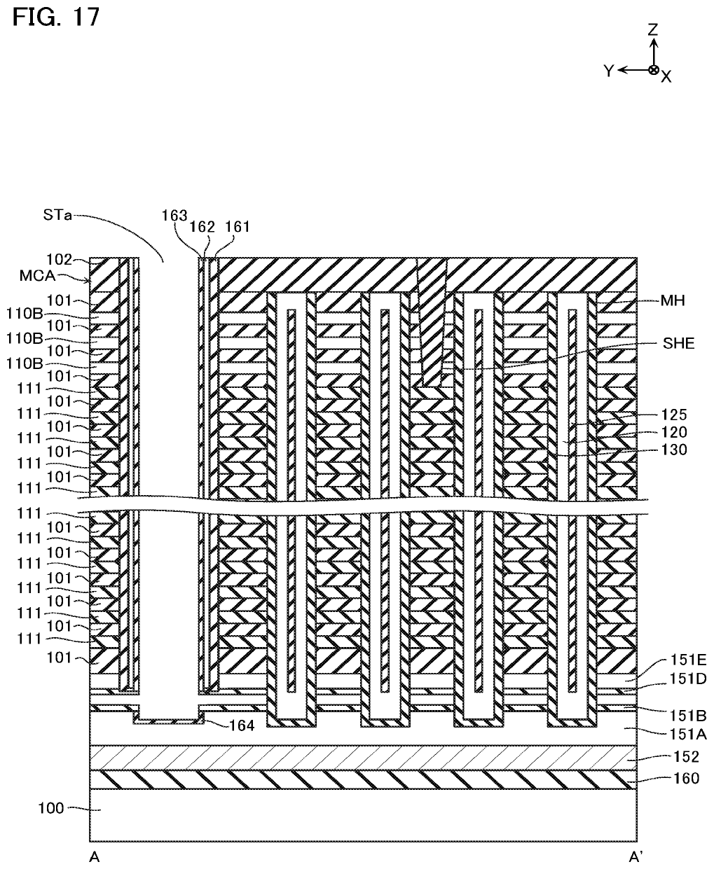

Next, as illustrated in FIG. 17, the sacrifice layer 151C is removed via the openings STa to partially expose the sidewalls of the gate insulating layers 130 of the memory hole structures MH. This process is performed by a method, such as wet etching. In this process, since the sacrifice layers 111 formed of the same kind of material as the sacrifice layer 151C are protected by the protective layers 163, the sacrifice layers 111 are not etched at the same time.

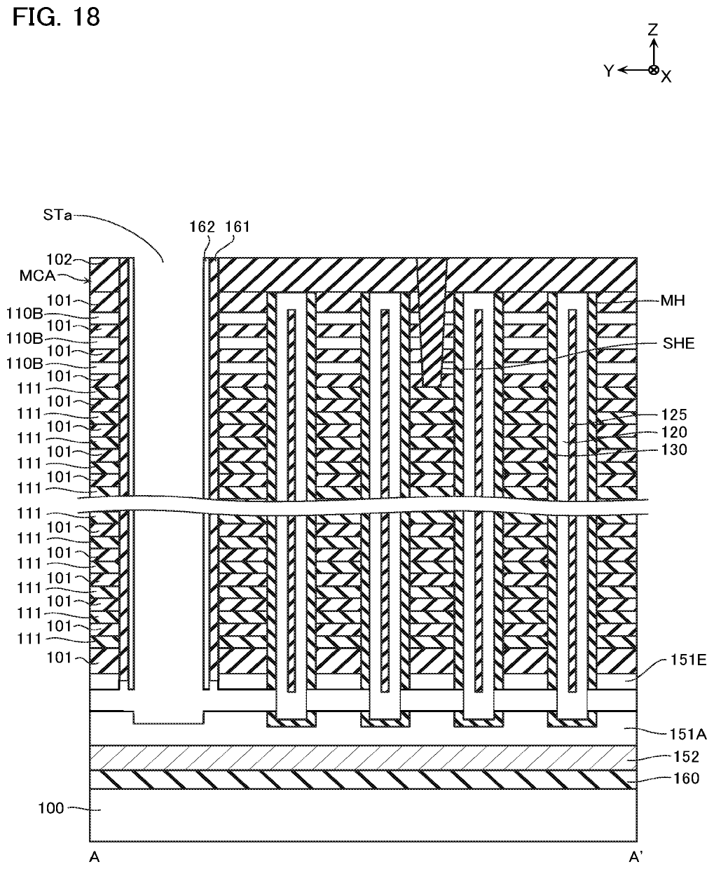

Next, as illustrated in FIG. 18, the gate insulating layers 130 are partially removed via the openings STa and cavities where the sacrifice layer 151C was provided to expose the side surfaces of the semiconductor layers 120. In this process, the insulating layer 151B, the insulating layer 151D, the protective layer 163, and the protective layer 164, which contain the same kind of material as the gate insulating layer 130, are also simultaneously removed. This process is performed by a method, such as chemical dry etching.

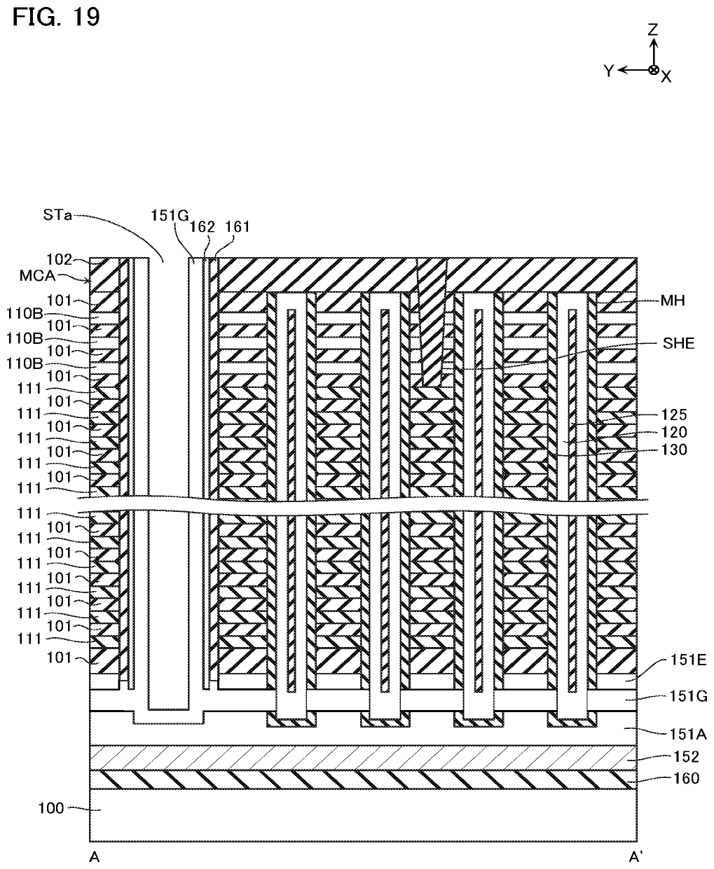

Next, as illustrated in FIG. 19, the semiconductor layer 151G of polysilicon (Si) or the like is formed on the side surfaces of the semiconductor layers 120, the upper surface of the semiconductor layer 151A, the lower surface of the semiconductor layer 151E, and the inner walls of the openings STa. This process is performed by a method, such as epitaxial growth of the semiconductor layer.

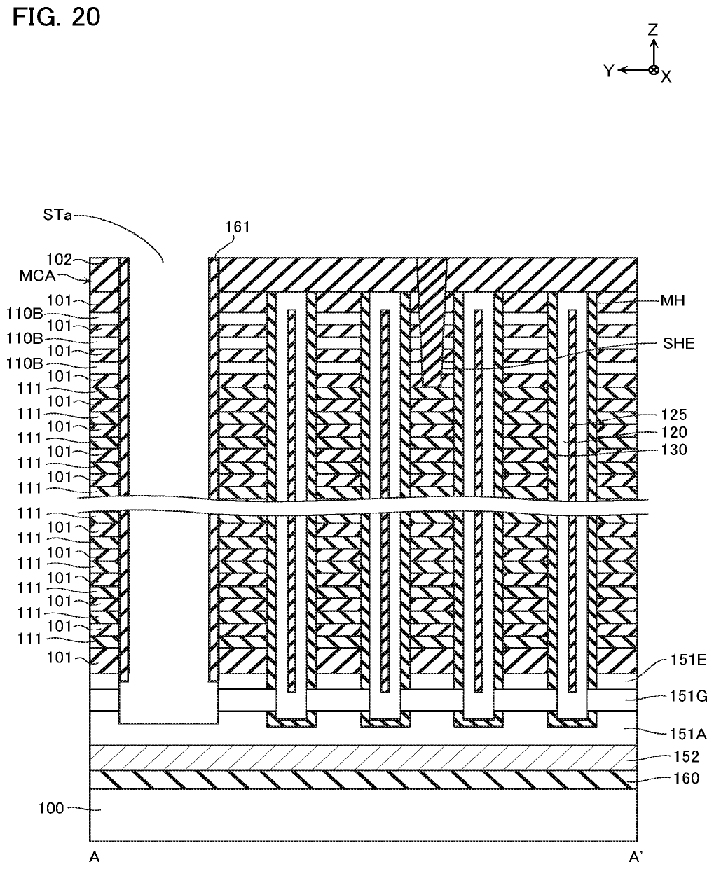

Next, as illustrated in FIG. 20, the semiconductor layer 151G on the inner wall portions of the openings STa and the semiconductor layers 162 are removed. At this time, parts of the bottom surface portions of the openings STa not covered with the insulating layers 161 expand. This process is performed by a method, such as wet etching.

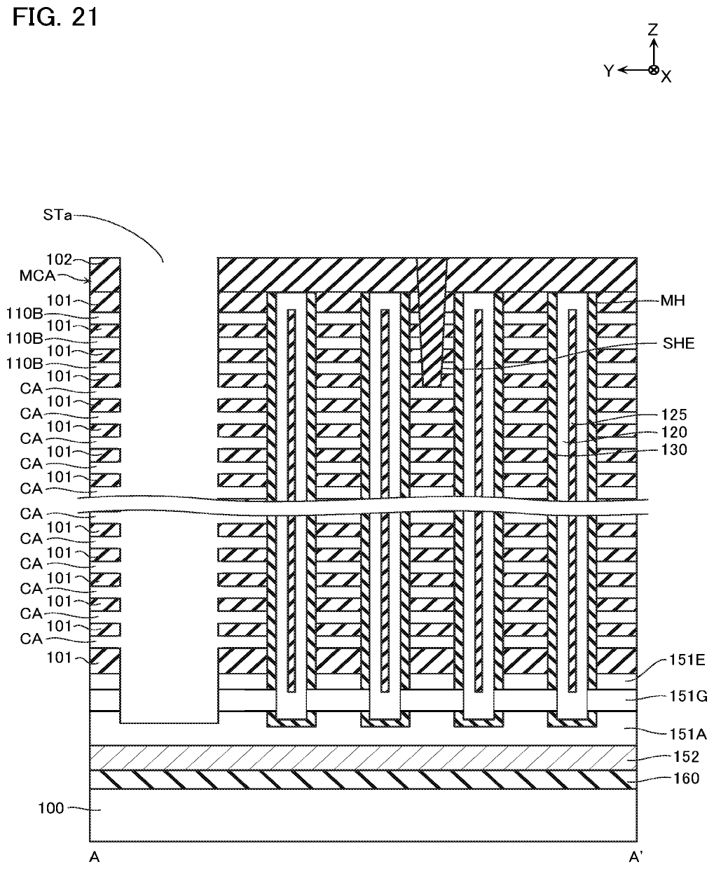

Next, as illustrated in FIG. 21, the insulating layers 161 covering the sidewalls of the openings STa are removed, and subsequently, the plurality of sacrifice layers 111 are removed via the openings STa to form cavities CA. This process is performed by a method, such as wet etching.

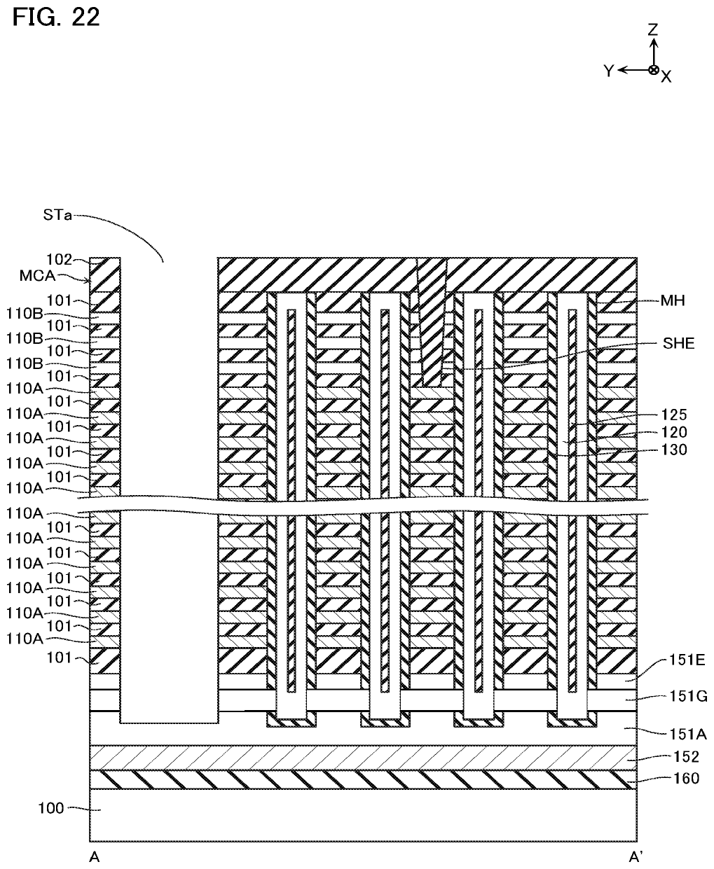

Next, as illustrated in FIG. 22, the plurality of conductive layers 110A are formed via the high-dielectric insulating layer 114 (FIG. 6) in the cavities CA formed by removing the sacrifice layers 111. The formation of the conductive layers 110A is performed by a method, such as CVD.

Next, the sidewall portions SW and the electrode portions LI are disposed in the openings STa, the contacts Ch and the contacts Cb are disposed on the upper portions of the memory hole structures MH, and the bit lines BL are disposed on the upper portions of the contacts Cb, thereby forming the configuration described with reference to FIG. 8.

### Effect of First Embodiment

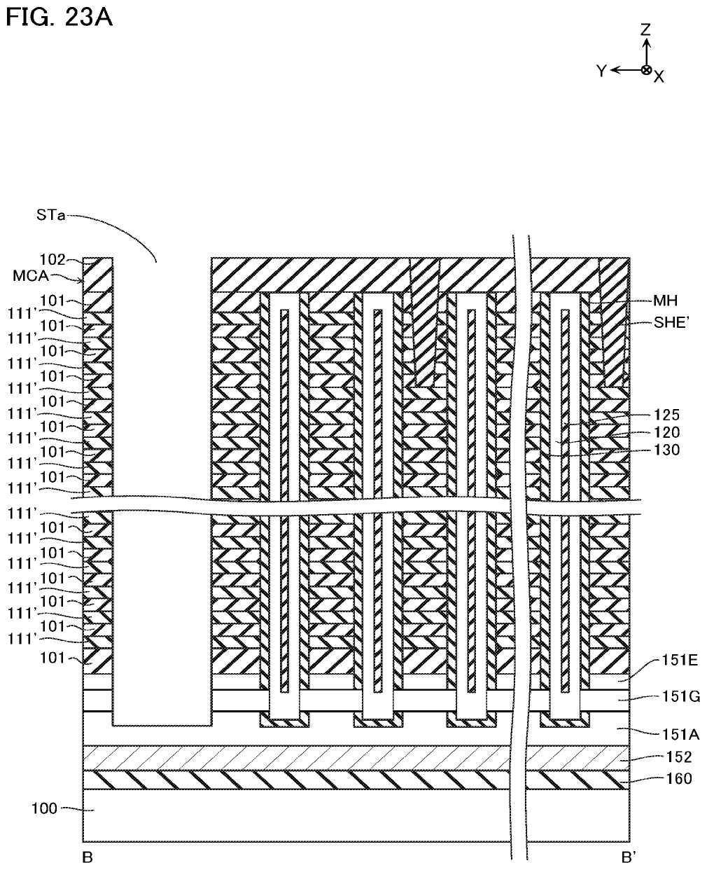

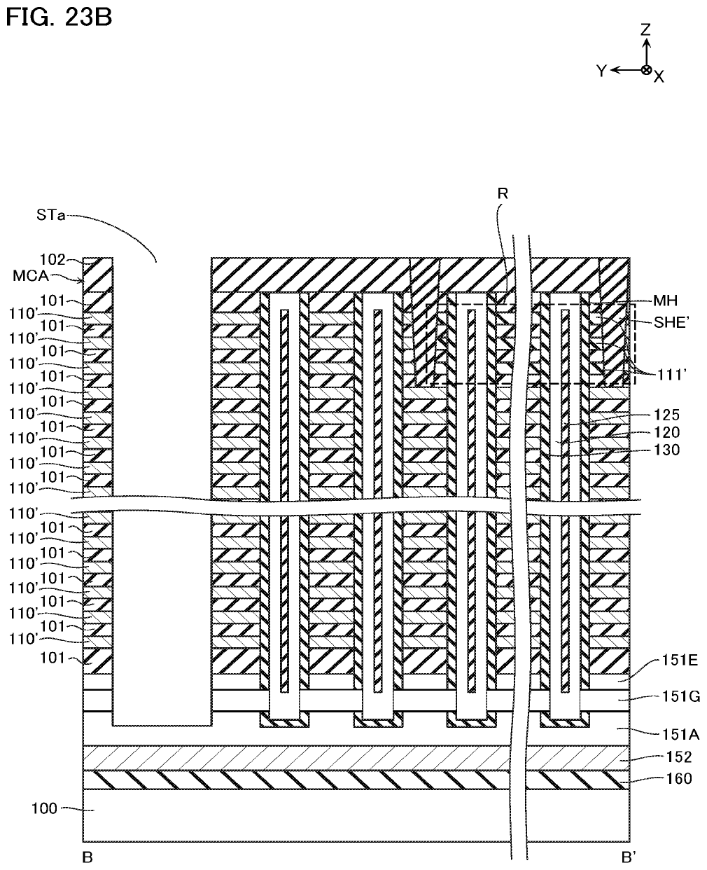

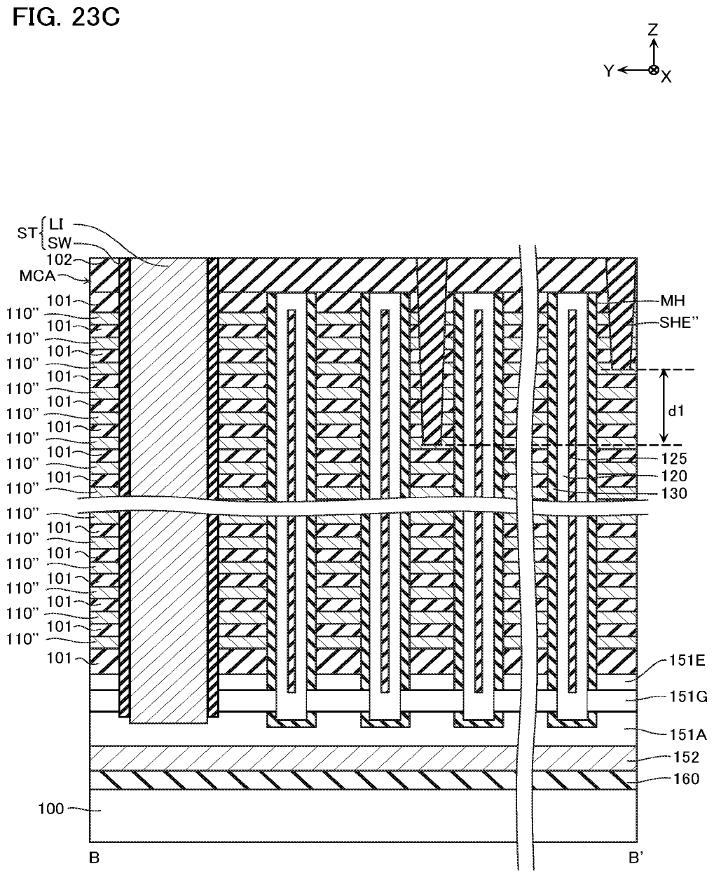

The effect of this embodiment will be described based on a comparative example 1 illustrated in FIG. 23A and FIG. 23B and a comparative example 2 illustrated in FIG. 23C. FIG. 23A and FIG. 23B are schematic cross-sectional views illustrating a method for manufacturing a semiconductor memory device according to the comparative example 1. FIG. 23C is a schematic cross-sectional view illustrating a method for manufacturing a semiconductor memory device according to the comparative example 2. FIG. 23A to FIG. 23C are schematic cross-sectional views of the structure illustrated in FIG. 7 taken along a line B-B′ viewed in an arrow direction.

In the process of the comparative example 1 illustrated in FIG. 23A, a stacked structure that includes one type of sacrifice layers 111′ and insulating layers 101 formed of the same material without the conductive layer 110B like this embodiment is disposed. Also in the comparative example 1, a plurality of insulating portions SHE′ arranged in the Y-direction are disposed like this embodiment.

Next, FIG. 23B illustrates a structure when the sacrifice layers 111′ are removed via the openings STa and conductive layers 110′ are formed in cavities formed by removing the sacrifice layers 111′. When a single memory block BLK includes three or more string units SU, that is, when two or more insulating portions SHE′ are disposed between the inter-block insulating layers ST, formation of the insulating portions SHE′ before the removal of the sacrifice layers 111′ does not allow a liquid of wet etching to intrude into the parts of the sacrifice layers 111′ in the region R between the plurality of insulating portions SHE′ arranged in the Y-direction, thereby failing to remove the parts. Accordingly, as illustrated in FIG. 23B, in the region R, the sacrifice layers 111′ remain and the conductive layers 110′ cannot be formed. Therefore, in the region R between the insulating portions SHE′, poor formation of the conductive layers 110′ that function as the electrode of the drain-side select transistors STD occurs.

In the comparative example 2, a case where insulating portions SHE″ are formed after forming conductive layers 110″ is illustrated in FIG. 23C. This structure does not include an etching stopper as a structure to control an etching depth in the Z-direction in processing the insulating portions SHE″ in a depth direction by RIE or the like. Therefore, it is not easy to control the depth of the insulating portion SHE″ in some cases. In other words, a processing deviation dl in the depth of the insulating portion SHE″ occurs. This processing variation causes an operational failure of the drain-side select transistor STD and the memory cell MC.

Therefore, in this embodiment, the conductive layers 110B that are also the gate electrodes of the drain-side select transistors STD are formed in a stacked structure at an early stage of the process as illustrated in FIG. 9. In this case, as illustrated in FIG. 13, the sacrifice layers 111 different in material from the conductive layers 110B can be used as the etching stopper in the formation of the insulating portions SHE, thereby facilitating the control of the insulating portions SHE in the depth direction. When the conductive layers 110 and the insulating layers 101 are further thinned for further high integration of the semiconductor memory device, a satisfactory process control in the depth direction can be performed. Accordingly, an effect of allowing the improved fabrication yield is provided also in the high integration of the semiconductor memory device.

In this embodiment, the memory hole structure MH is integrally formed in the Z-direction so as to be opposed to each of the conductive layers 110A that function as the word lines WL and the conductive layers 110B that function as the drain-side select gate lines SGD. This structure in which the memory hole structure MH is integrally formed can reduce the number of manufacturing processes compared with a structure in which the memory hole structure MH is formed in different processes in the respective regions corresponding to the word lines WL and the drain-side select gate lines SGD. Accordingly, in this embodiment, the semiconductor memory device can be manufactured at lower cost. Since the semiconductor layer 120 is integrally formed in the memory cell MC and the drain-side select transistor STD, a channel resistance of the memory string MS can be decreased compared with the structure in which the memory hole structure MH is formed in the different processes.

In this embodiment, a plurality of conductive layers 110B that function as the drain-side select gate lines SGD are disposed. With the plurality of conductive layers 110B, it is facilitated to control an amount and a depth of carrier injection to the electric charge accumulating layer 132 opposed to each of the conductive layers 110B compared with a case where, for example, a single conductive layer wide in the Z-direction is disposed. Accordingly, the structure in this embodiment can perform a threshold control in the channel region with higher accuracy.

### Modification

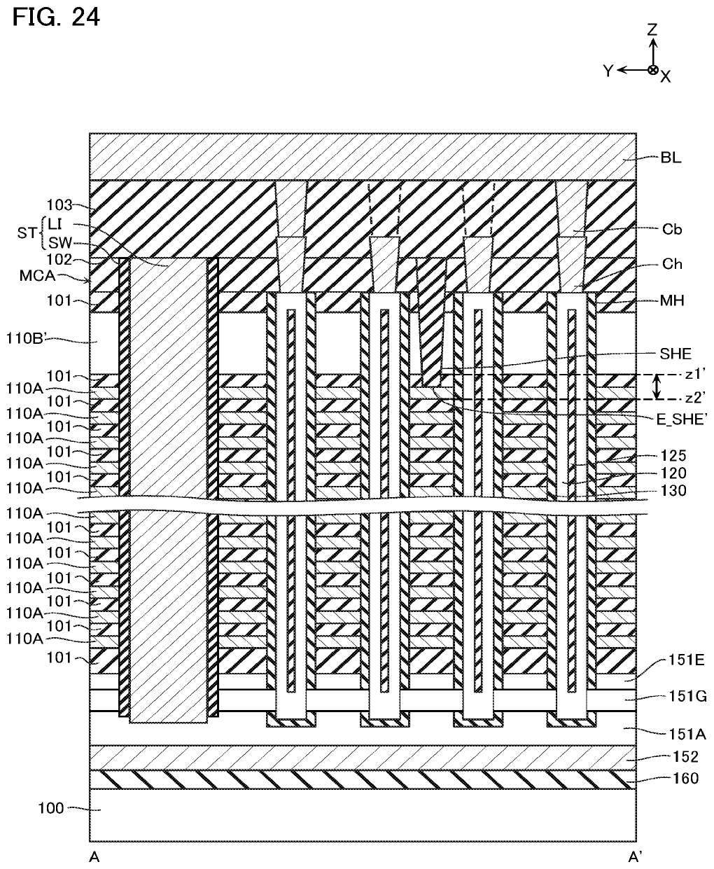

The number of the conductive layers 110B that function as the drain-side select gate lines SGD does not necessarily need to be plural. FIG. 24 is a schematic cross-sectional view of a semiconductor memory device according to the modification. In the modification, only a single layer of conductive layer 110B′ is formed as the drain-side select gate line SGD. In this case, the conductive layer 110B′ may be formed to be thick in the Z-direction compared with the conductive layer 110B, which is provided in plural layers.

As illustrated in FIG. 24, a position of a lower end surface of the conductive layer 110B′ is defined as a position z1′. A position of a lower end surface of the conductive layer 110A closest to the conductive layer 110B′ among the plurality of conductive layers 110A is defined as a position z2′. A lower end portion E_SHE′ in the Z-direction of the insulating portion SHE is disposed at a position below the position z1′ including the position z1′ and above the position z2′ not including the position z2′. For example, the lower end portion E_SHE′ is disposed so as to be in contact with the conductive layer 110A′ closest to the conductive layer 110B′ among the plurality of conductive layers 110A′. Since the insulating portion SHE is disposed at such a position, the insulating portion SHE separates the conductive layer 110B′ into two or more in the Y-direction but does not separate the conductive layers 110A. In other words, the plurality of conductive layers 110A are continuously disposed between the inter-block insulating layers ST. At least one of the lower end portions E_SHE′ may be disposed so as to be in contact with the conductive layer 110A closest to the conductive layer 110B′ among the plurality of conductive layers 110A.

### Effect of Modification

In this modification, since only a single layer of the conductive layer 110B′ is disposed, the number of the manufacturing processes of the layer formation is more reduced compared with the case where a plurality of conductive layers are formed. Accordingly, in this modification, the semiconductor memory device can be manufactured at lower cost.

### Second Embodiment

### Configuration

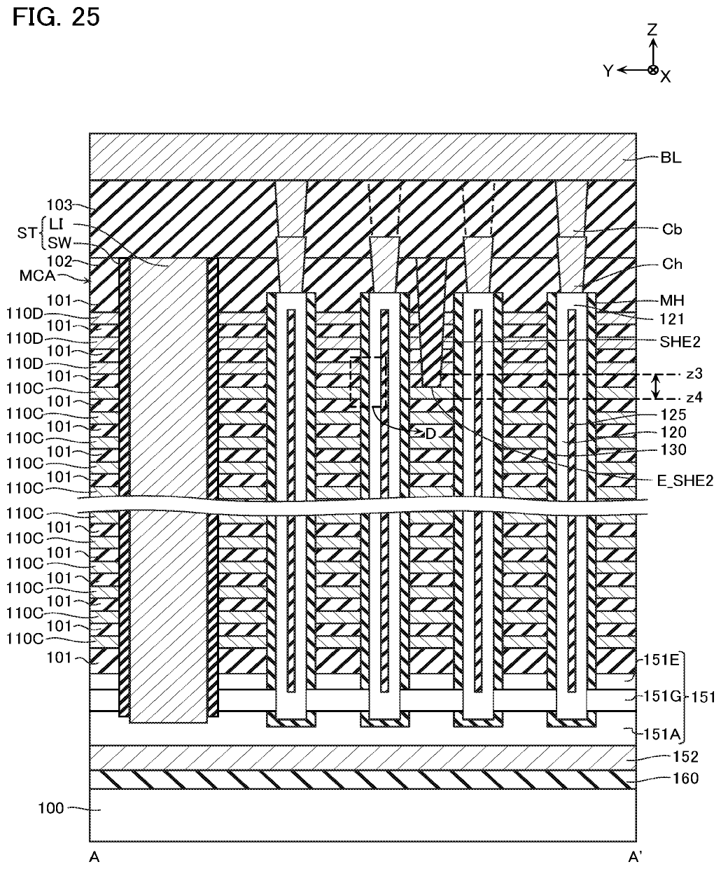

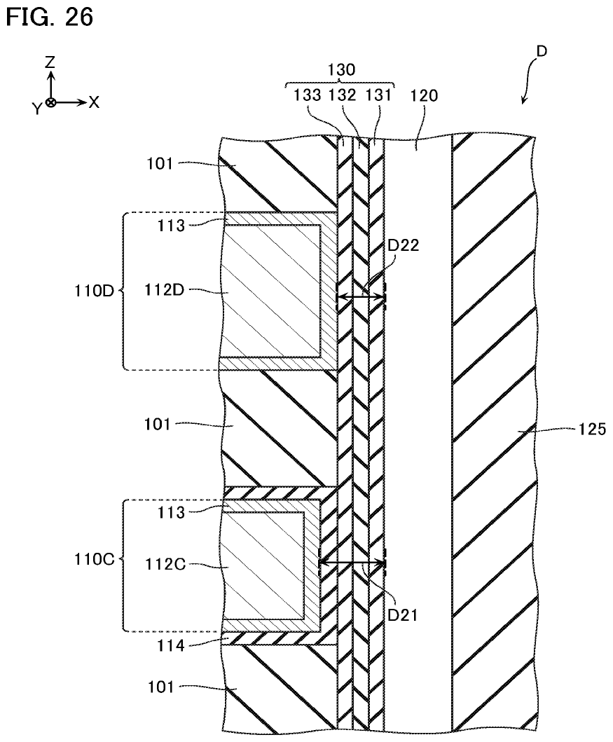

Next, with reference to FIG. 25 and FIG. 26, a configuration of a semiconductor memory device according to the second embodiment will be described. FIG. 25 is a schematic cross-sectional view illustrating an exemplary configuration of the semiconductor memory device according to the second embodiment. FIG. 26 is a schematic cross-sectional view of a part indicated as D in FIG. 25.

As illustrated in FIG. 25, the semiconductor memory device according to the embodiment is basically configured similarly to the semiconductor memory device according to the first embodiment. However, the semiconductor memory device according to the embodiment includes conductive layers 110C instead of the conductive layers 110A, and conductive layers 110D instead of the conductive layers 110B.

The plurality of conductive layers 110C are disposed in the Z-direction via the insulating layers 101, and the conductive layers 110C are conductive layers that have approximately plate shapes and extend in the X-direction and the Y-direction. As illustrated in FIG. 26, the conductive layer 110C includes a conductive film 112C and a barrier metal film 113 that covers an upper surface, a lower surface, and a side surface of this conductive film 112C. These upper surface, lower surface, and side surface of the barrier metal film 113 are covered with a high-dielectric insulating layer 114. The conductive film 112C is a metal film of molybdenum (Mo) or the like. The barrier metal film 113 is a metal film of titanium nitride (TiN) or the like. The high-dielectric insulating layer 114 is a metal oxide film of alumina (Al₂O₃) or the like.

The conductive layers 110C function as the word lines WL (FIG. 3) and the gate electrodes of the plurality of memory cells MC (FIG. 3) connected to the word lines WL. A part of the conductive layers 110C disposed downward among the plurality of conductive layers 110C functions as the source-side select gate line SGS (FIG. 3) and the gate electrodes of the plurality of source-side select transistor STS (FIG. 3) connected thereto.

One or a plurality of conductive layer 110D are disposed in the Z-direction via the insulating layer 101, and the conductive layer 110D is a conductive layer that extends in the X-direction and the Y-direction and has an approximately plate shape. As illustrated in FIG. 26, the conductive layer 110D includes a conductive film 112D and a barrier metal film 113 that covers an upper surface, a lower surface, and a side surface of this conductive film 112D. The conductive film 112D is a conductive film of tungsten (W) or the like. The barrier metal film 113 is a metal film of titanium nitride (TiN) or the like.

The conductive layers 110D are disposed above the plurality of conductive layers 110C via the insulating layers 101, and function as the drain-side select gate line SGD (FIG. 3) and the gate electrodes of the plurality of drain-side select transistors STD (FIG. 3) connected to this drain-side select gate line SGD.

As illustrated in FIG. 26, while the barrier metal film 113 and the high-dielectric insulating layer 114 are disposed between the conductive film 112C and the semiconductor layer 120, the high-dielectric insulating layer 114 is not disposed between the conductive layer 110D and the semiconductor layer 120 while the barrier metal film 113 is disposed. Accordingly, a distance D21 between the conductive layer 110C and the semiconductor layer 120 is greater than a distance D22 between the conductive layer 110D and the semiconductor layer 120 by a length corresponding to the thickness of the high-dielectric insulating layer 114.

As illustrated in FIG. 25, a position of a lower end surface of the conductive layer 110D closest to the conductive layer 110C among the plurality of conductive layers 110D is defined as a position z3. A position of a lower end surface of the conductive layer 110C closest to the conductive layer 110D among the plurality of conductive layers 110C is defined as a position z4. A lower end portion E_SHE2 in the Z-direction of an insulating portion SHE2 is disposed at a position below the position z3 including the position z3 and above the position z4 not including the position z4. Since the insulating portion SHE2 is disposed at such a position, the insulating portion SHE2 separates the conductive layers 110D into two or more in the Y-direction but does not separate the conductive layers 110C. In other words, the plurality of conductive layers 110C are continuously disposed between the inter-block insulating layers ST. At least one of the lower end portions E_SHE2 may be disposed so as to be in contact with the conductive layer 110C closest to the conductive layer 110D among the plurality of conductive layers 110C.

### Manufacturing Method

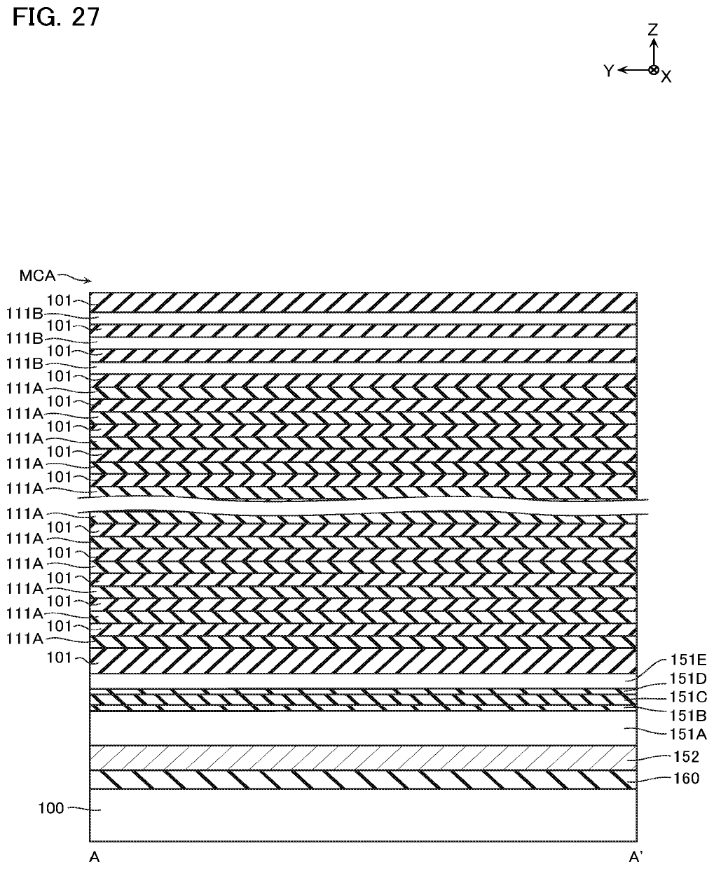

Next, with reference to FIG. 27 to FIG. 41, the method for manufacturing the semiconductor memory device according to the embodiment will be described. FIG. 27 to FIG. 41 illustrate cross-sectional surfaces taken along the line A-A′ in FIG. 7. Similar reference numerals are attached to components similar to those in the first embodiment, thereby omitting the description in some cases.

As illustrated in FIG. 27, in this manufacturing method, the insulating layer 160, the conductive layer 152, the semiconductor layer 151A, the insulating layer 151B, the sacrifice layer 151C, the insulating layer 151D, and the semiconductor layer 151E are formed on the substrate 100. The plurality of insulating layers 101 and sacrifice layers 111A as first films are alternately formed thereabove. The plurality of insulating layers 101 and sacrifice layers 111B as second films are alternately formed thereabove.

The sacrifice layer 111A is an insulating layer of silicon nitride (SiN) or the like. The sacrifice layer 111B is, for example, a semiconductor layer of non-doped polysilicon (Si) or polysilicon (Si) doped with phosphorus (P).

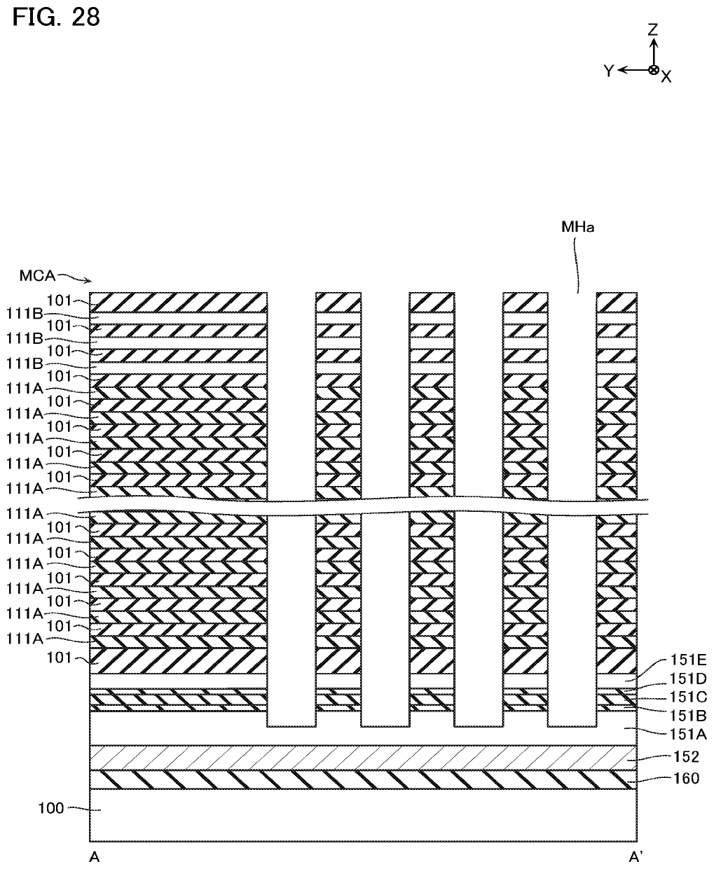

Next, as illustrated in FIG. 28, openings MHa are formed. The openings MHa extend in the Z-direction, and penetrate the insulating layers 101, the sacrifice layers 111B, the sacrifice layers 111A, the semiconductor layer 151E, the insulating layer 151D, the sacrifice layer 151C, and the insulating layer 151B to expose the semiconductor layer 151A.

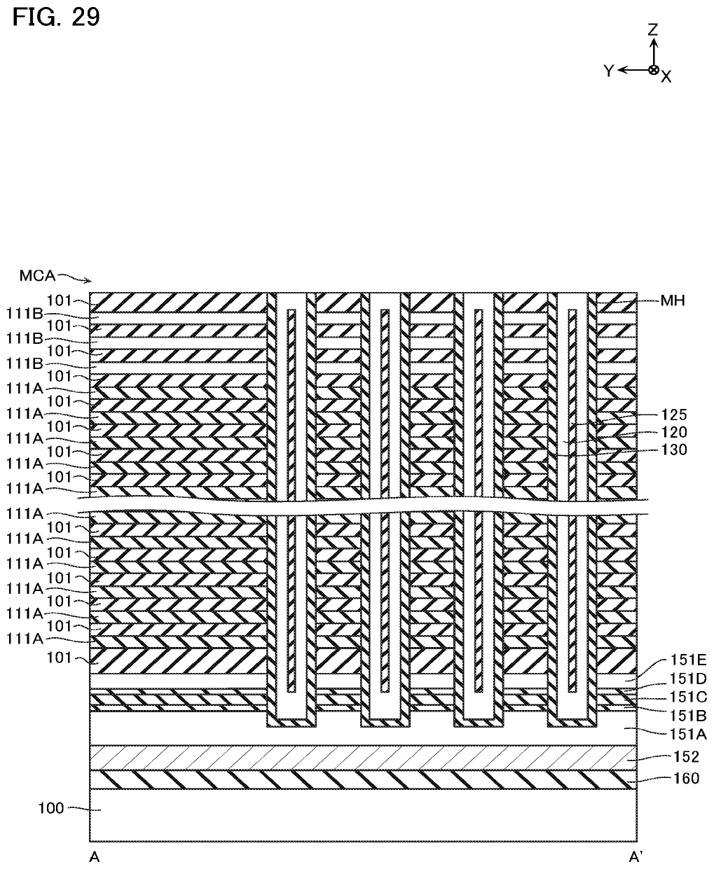

Next, as illustrated in FIG. 29, the gate insulating layers 130, the semiconductor layers 120, and the insulating layers 125 are formed on inner peripheral surfaces of the openings MHa.

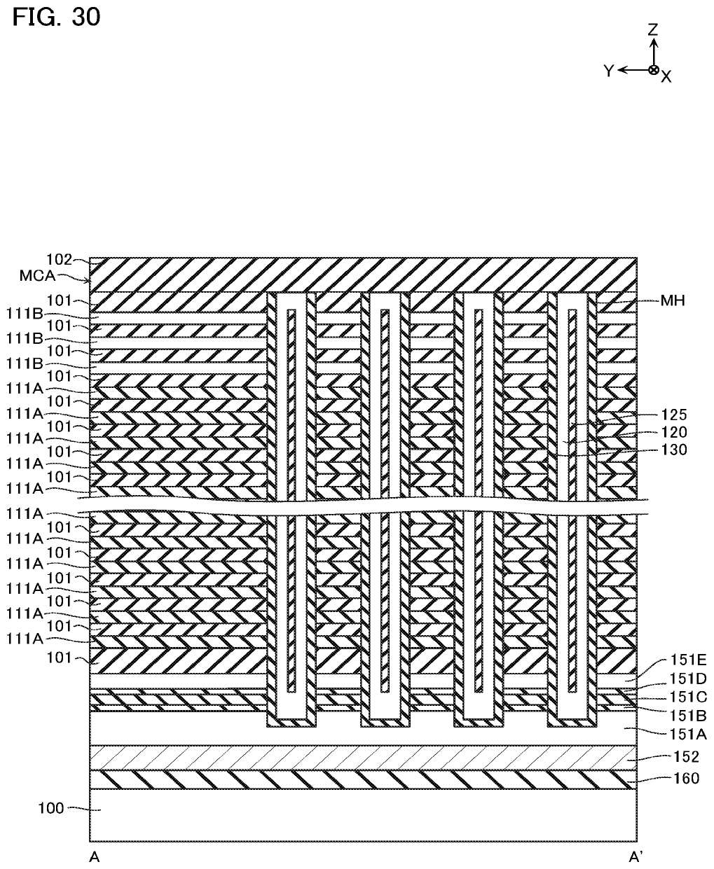

Next, as illustrated in FIG. 30, an insulating layer 102 of silicon oxide (SiO₂) or the like is formed on an upper surface of the structure illustrated in FIG. 29.

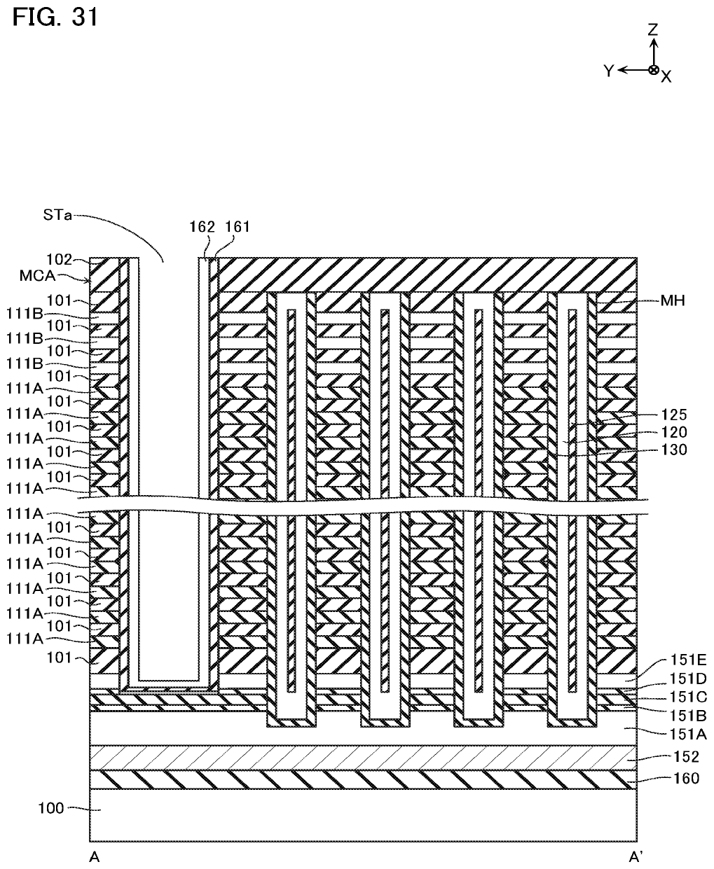

Next, as illustrated in FIG. 31, openings STa are formed. The opening STa extends in the X-direction and the Z-direction, and separates the plurality of sacrifice layers 111B and layers 111A in the Y-direction. The opening STa penetrates the insulating layer 102, the insulating layers 101, the sacrifice layers 111B, the sacrifice layers 111A, and the semiconductor layer 151E in the Z-direction to expose the insulating layer 151D.

As illustrated in FIG. 31, an insulating layer 161 of silicon oxide (SiO₂) or the like and a semiconductor layer 162 of amorphous silicon (Si) or the like are formed on an inner wall surface and a bottom surface of the opening STa.

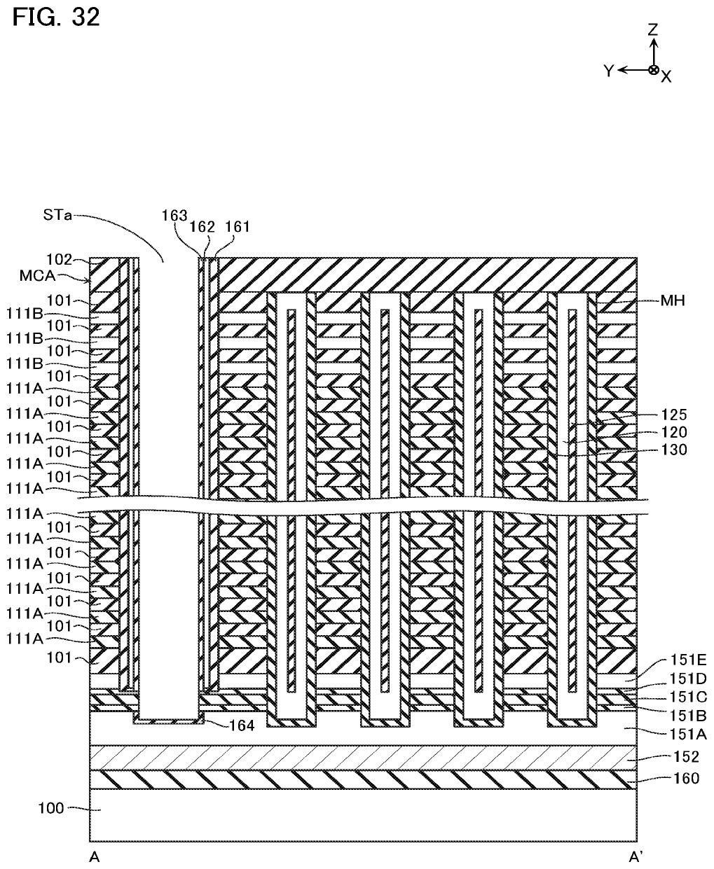

Next, as illustrated in FIG. 32, the bottom surfaces of the openings STa are dug down to the semiconductor layer 151A. Then, protective layers 163 are formed on exposed portions of the semiconductor layers 162 in the inner wall surfaces of the openings STa, and protective layers 164 are formed on the bottom surfaces of the openings STa.

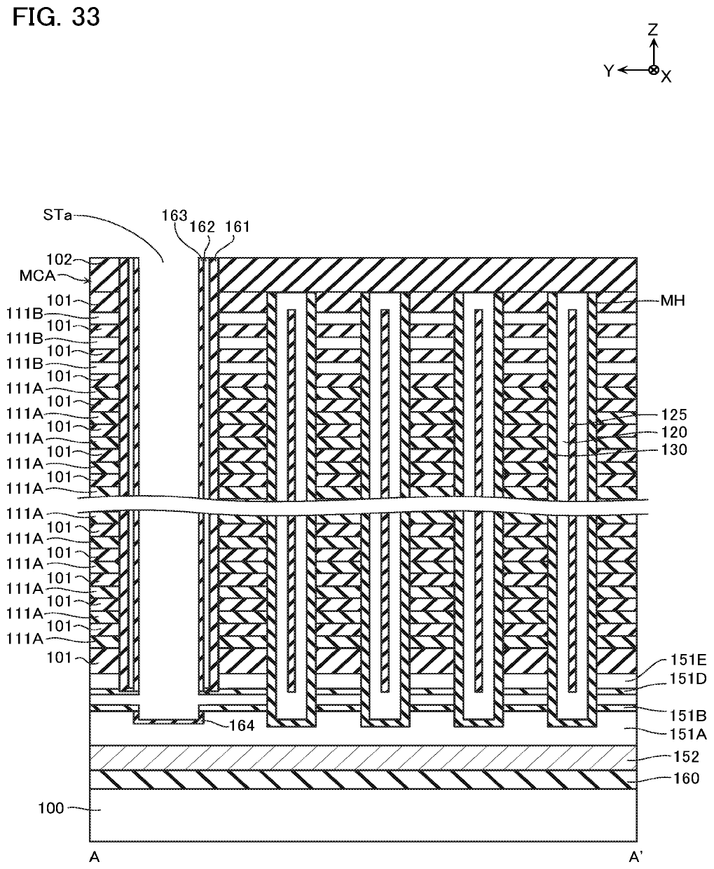

Next, as illustrated in FIG. 33, the sacrifice layer 151C is removed via the openings STa to partially expose the sidewalls of the gate insulating layers 130 of the memory hole structures MH. In this process, since the sacrifice layers 111A formed of the same kind of material as the sacrifice layer 151C are protected by the protective layers 163, the sacrifice layers 111A are not etched at the same time.

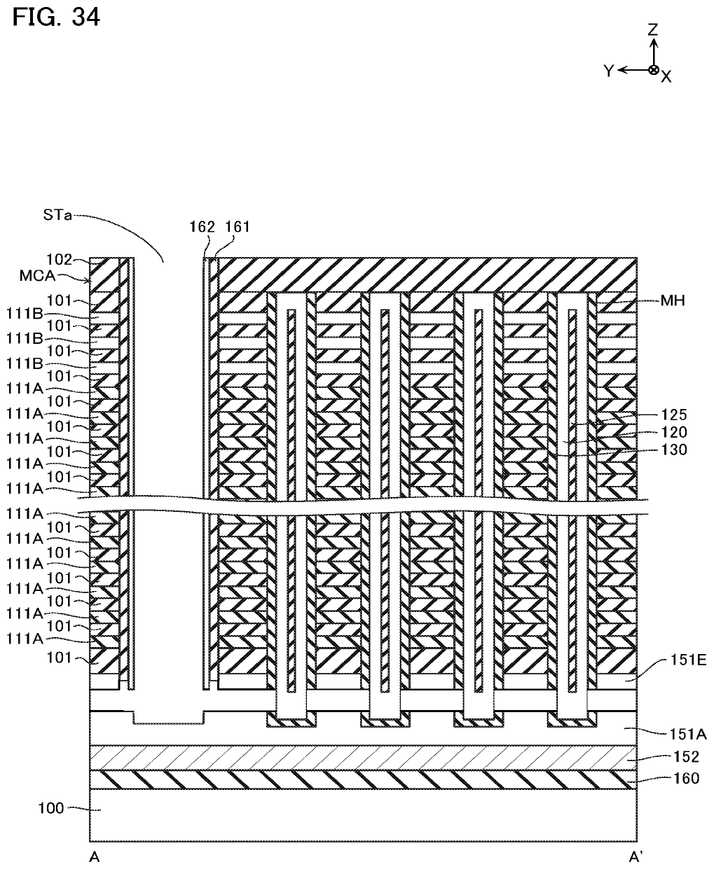

Next, as illustrated in FIG. 34, the gate insulating layers 130 are partially removed via the openings STa and cavities where the sacrifice layer 151C was provided to expose the side surfaces of the semiconductor layers 120. In this process, the insulating layer 151B, the insulating layer 151D, the protective layer 163, and the protective layer 164, which contain the same kind of material as the gate insulating layer 130, are also simultaneously removed.

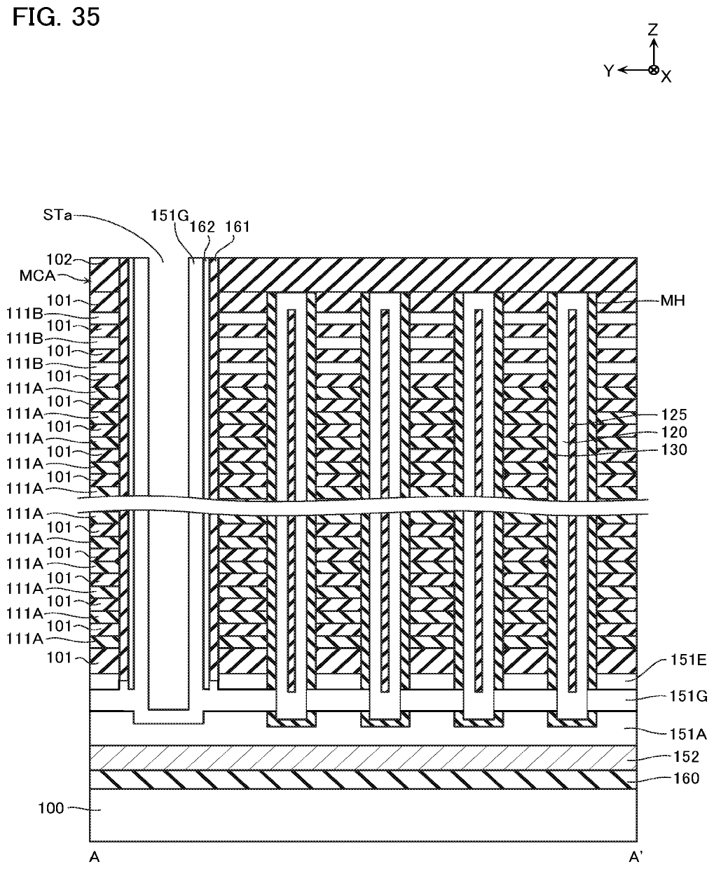

Next, as illustrated in FIG. 35, the semiconductor layer 151G of polysilicon (Si) or the like is formed on the side surfaces of the semiconductor layers 120, the upper surface of the semiconductor layer 151A, the lower surface of the semiconductor layer 151E, and the inner walls of the openings STa.

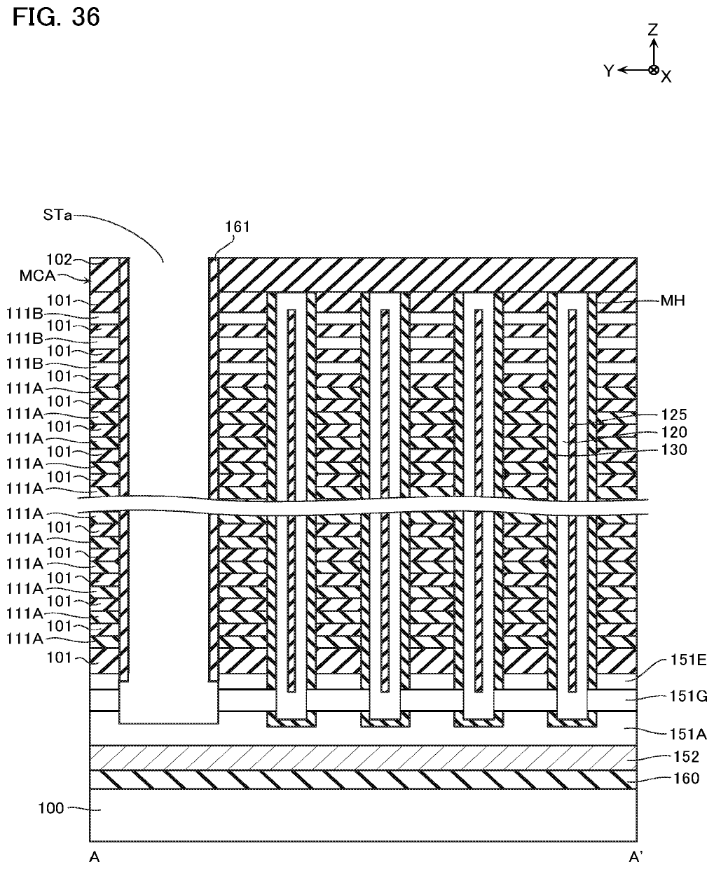

Next, as illustrated in FIG. 36, the semiconductor layer 151G on the inner wall portions of the openings STa and the semiconductor layers 162 are removed. At this time, parts of the bottom surface portions of the openings STa not covered with the insulating layers 161 expand.

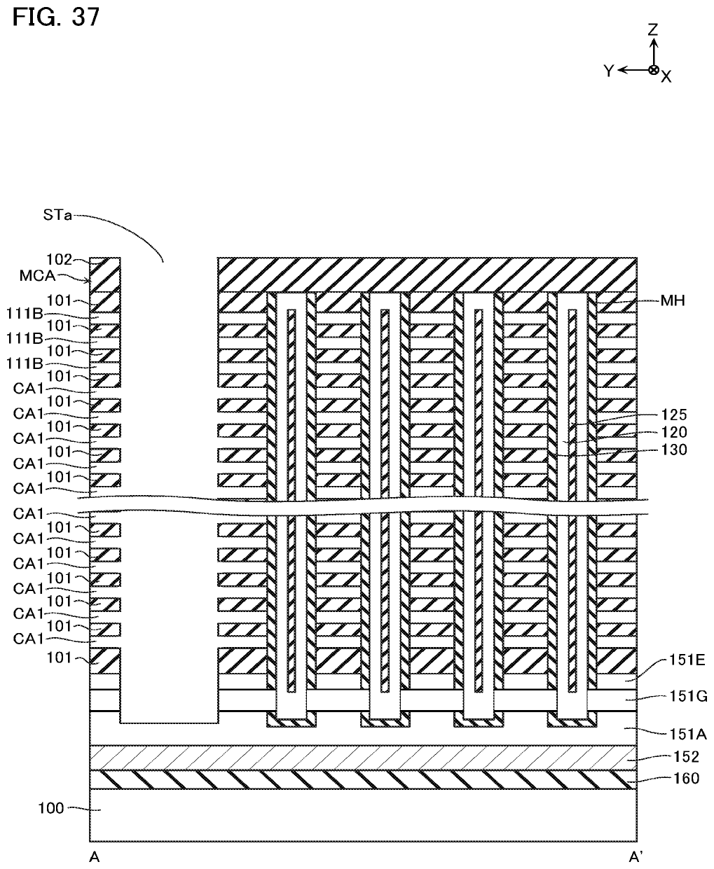

Next, as illustrated in FIG. 37, the insulating layers 161 covering the sidewalls of the openings STa are removed, and subsequently, the plurality of sacrifice layers 111A are removed via the openings STa to form first cavities CA1. This process is performed by a method, such as wet etching.

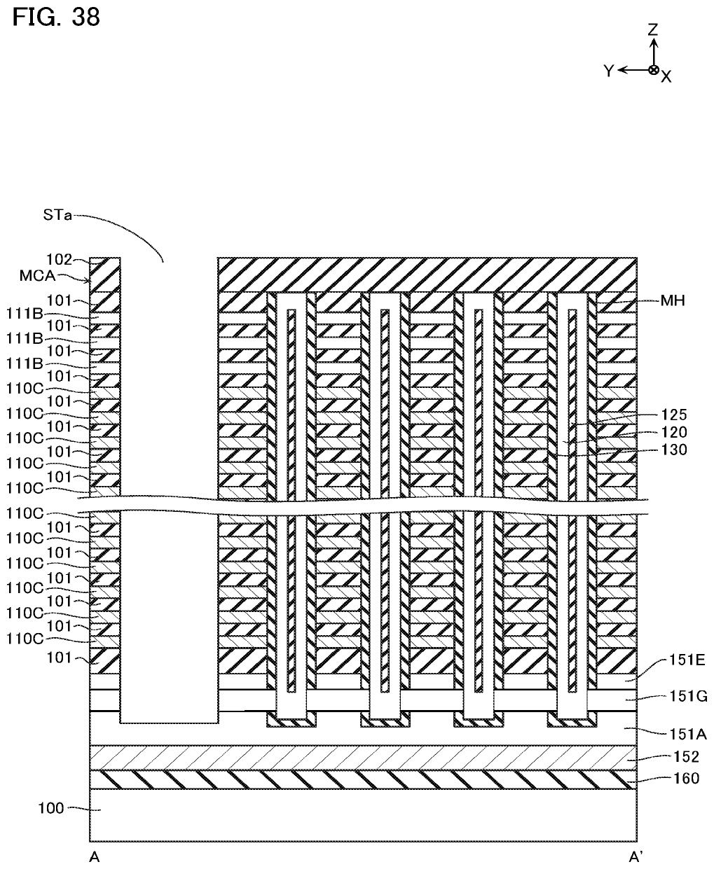

Next, as illustrated in FIG. 38, the plurality of conductive layers 110C are formed via the high-dielectric insulating layer 114 (FIG. 26) in the first cavities CA1 formed by removing the sacrifice layers 111A. The formation of the conductive layers 110C is performed by a method, such as CVD.

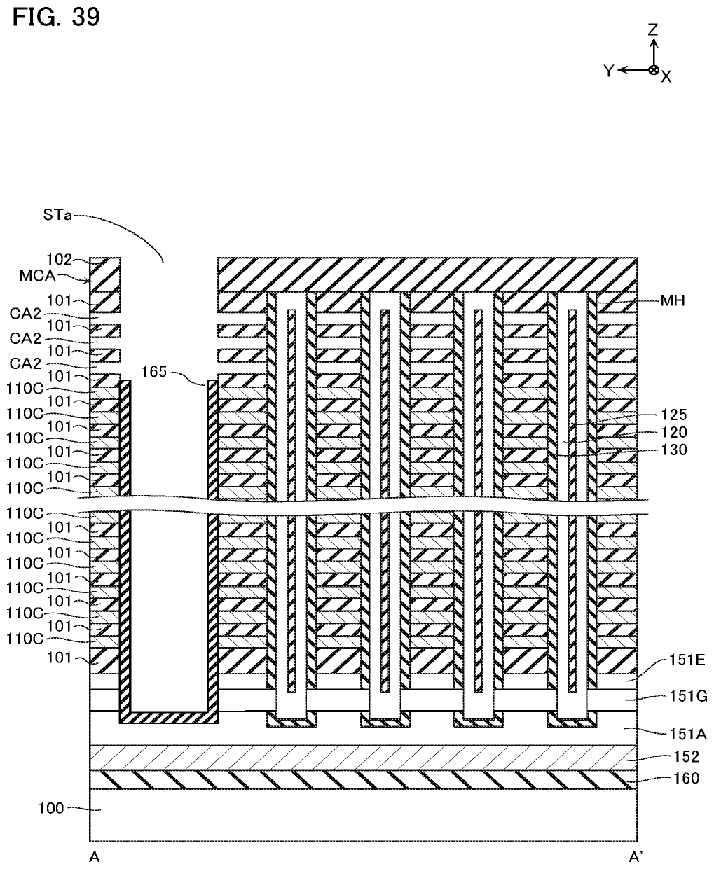

Next, as illustrated in FIG. 39, protective layers 165 are formed on the inner wall portions of the openings STa, and the protective layers 165 are etchbacked so as to expose the sacrifice layers 111B. The formation of the protective layers 165 is performed by, for example, a method in which CVD, etchback, and the like are used in combination.

As illustrated in FIG. 39, the plurality of sacrifice layers 111B are removed via the openings STa, thus forming second cavities CA2. This process is performed by a method, such as wet etching.

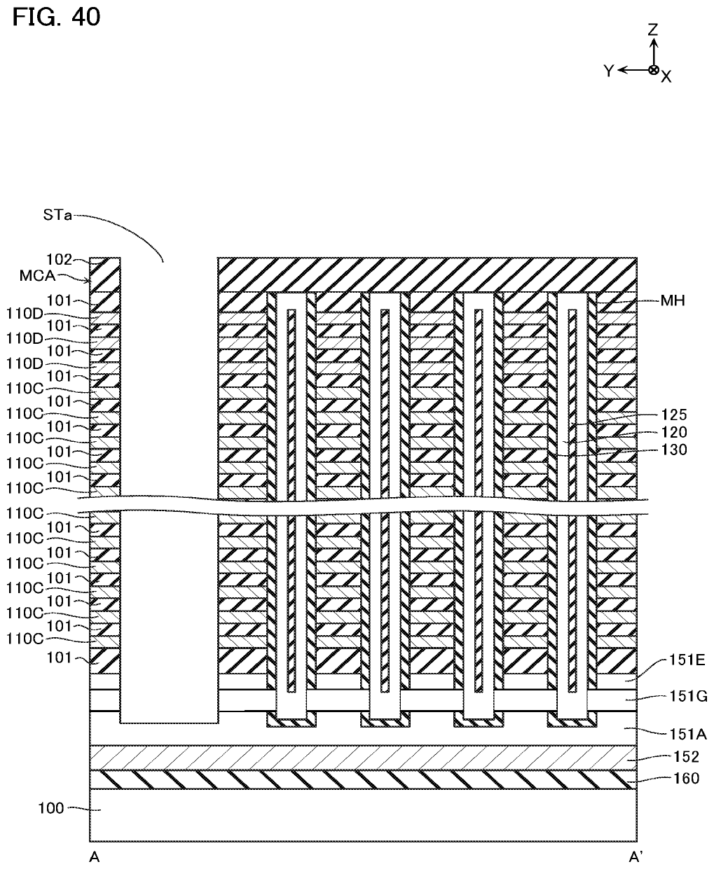

Next, as illustrated in FIG. 40, the plurality of conductive layers 110D are formed in the second cavities CA2 formed by removing the sacrifice layers 111B. The formation of the conductive layers 110D is performed by a method, such as CVD.

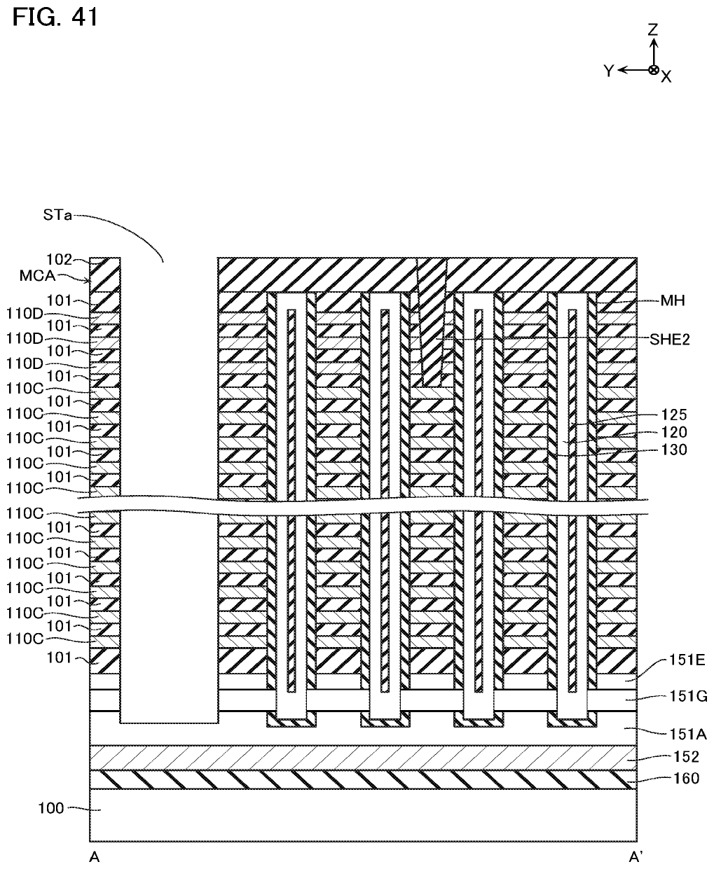

Next, as illustrated in FIG. 41, insulating portions SHE2 are formed. The insulating portion SHE2 extends in the X-direction and the Z-direction, and separates the plurality of conductive layers 110D in the Y-direction. The insulating portion SHE2 is formed by forming an opening that penetrates the insulating layer 102, the insulating layers 101, and the conductive layers 110D to expose the uppermost layer of the plurality of conductive layers 110C using the conductive layer 110C as an etching stopper in the Z-direction, and embedding the insulating layers in the opening. This process is performed by a method, such as RIE, CVD, and the like.

Next, the sidewall portions SW and the electrode portions LI are disposed in the openings STa, the contacts Ch and the contacts Cb are disposed on the upper portions of the memory hole structures MH, and the bit lines BL are disposed on the upper portions of the contacts Cb, thereby forming the configuration described with reference to FIG. 25.

### Effect of Second Embodiment

In this embodiment, the insulating portion SHE2 has a structure that separates the plurality of conductive layers 110D in the Y-direction. In this embodiment, as illustrated in FIG. 41, the conductive layer 110C formed of a material different from that of the conductive layer 110D can be used as the etching stopper in processing the insulating portion SHE2 in the depth direction by RIE or the like. Accordingly, an effect of facilitating the control of the depth of the insulating portion SHE2 is provided. Therefore, the fabrication yield of the semiconductor memory device can be improved.

### Other Embodiments

In this embodiment, the memory layer ML is disposed above the circuit layer CL. Meanwhile, it is possible to employ a structure in which a first substrate that includes a circuit layer CL and a second substrate that includes a memory layer ML are manufactured in different processes, bonding electrodes are disposed on upper surfaces of the respective substrates, and the first substrate and the second substrate are mutually bonded by the bonding electrodes, thus having the same function as the first or the second embodiment.

### Others

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor memory device comprising:
a plurality of first conductive layers disposed to be mutually separated in a first direction, the plurality of first conductive layers extending in a second direction intersecting with the first direction;
a second conductive layer disposed to be separated from the plurality of first conductive layers in the first direction, the second conductive layer extending in the second direction;
a semiconductor layer that extends in the first direction, the semiconductor layer being integrally formed in the first direction and being opposed to the plurality of first conductive layers and the second conductive layer;
a gate insulating layer disposed between the plurality of first conductive layers and the semiconductor layer and between the second conductive layer and the semiconductor layer;
a plurality of first insulating portions that extend in the first direction and the second direction in the plurality of first conductive layers and the second conductive layer, the plurality of first insulating portions separating the plurality of first conductive layers and the second conductive layer in a third direction intersecting with the first direction and the second direction; and
a plurality of second insulating portions that extend in the first direction and the second direction in the second conductive layer, at least one second insulating portion of the plurality of second insulating portions being disposed between first insulating portions of the plurality of first insulating portions mutually adjacent in the third direction, the at least one second insulating portion separating the second conductive layer in the third direction into two or more between the first insulating portions mutually adjacent in the third direction, wherein
the plurality of first conductive layers are each continuously formed between the first insulating portions mutually adjacent in the third direction, and the plurality of first conductive layers contain a first material, and
the second conductive layer contains a second material different from the first material.

2. The semiconductor memory device according to claim 1, wherein
at least two second insulating portions of the plurality of second insulating portions are disposed between the first insulating portions mutually adjacent in the third direction,
the at least two second insulating portions separate the second conductive layer in the third direction into three or more between the first insulating portions mutually adjacent in the third direction.

3. The semiconductor memory device according to claim 1, further comprising
a plurality of the semiconductor layers disposed in the second direction and the third direction, wherein
the plurality of semiconductor layers include:
a plurality of first semiconductor layers disposed at positions separated from the at least one second insulating portion between the first insulating portions mutually adjacent in the third direction; and
a plurality of second semiconductor layers disposed in the second direction to be in contact with the at least one second insulating portion between the first insulating portions mutually adjacent in the third direction.

4. The semiconductor memory device according to claim 1, wherein
one end portion in the first direction of at least one of the plurality of second portions is in contact with a first conductive layer closest to the second conductive layer among the plurality of first conductive layers.

5. The semiconductor memory device according to claim 1, wherein
a metal oxide film is disposed between the plurality of first conductive layers and the gate insulating layer, and
a distance between the plurality of first conductive layers and the semiconductor layer is greater than a distance between the second conductive layer and the semiconductor layer.

6. The semiconductor memory device according to claim 1, wherein
the first material contains tungsten or molybdenum, and the second material contains polysilicon.

7. The semiconductor memory device according to claim 6, wherein
the plurality of first conductive layers each include a first conductive film and a barrier metal film, the first conductive film contains tungsten or molybdenum, the barrier metal film is disposed to cover the first conductive film, and the barrier metal film is interposed between the first conductive film and the gate insulating layer,
the second conductive layer includes a second conductive film that contains polysilicon, and the second conductive film is not covered with a barrier metal film, and
a distance between the first conductive film and the semiconductor layer is greater than a distance between the second conductive film and the semiconductor layer.

8. The semiconductor memory device according to claim 1, wherein
the first material contains molybdenum, and the second material contains tungsten.

9. A semiconductor memory device comprising:
a plurality of first conductive layers disposed to be mutually separated in a first direction, the plurality of first conductive layers extending in a second direction intersecting with the first direction;
a plurality of second conductive layers disposed to be mutually separated in a first direction and to be separated from the plurality of first conductive layers in the first direction, the plurality of second conductive layers extending in the second direction;
a semiconductor layer that extends in the first direction, the semiconductor layer being opposed to the plurality of first conductive layers and the plurality of second conductive layers;
a gate insulating layer disposed between the plurality of first conductive layers and the semiconductor layer and between the plurality of second conductive layers and the semiconductor layer;
a plurality of first insulating portions that extend in the first direction and the second direction in the plurality of first conductive layers and the plurality of second conductive layers, the plurality of first insulating portions separating the plurality of first conductive layers and the plurality of second conductive layers in a third direction intersecting with the first direction and the second direction; and
a plurality of second insulating portions that extend in the first direction and the second direction in the plurality of second conductive layers, at least one second insulating portion of the plurality of second insulating portions being disposed between first insulating portions of the plurality of first insulating portions mutually adjacent in the third direction, the at least one second insulating portion separating the plurality of second conductive layers in the third direction into two or more between the first insulating portions mutually adjacent in the third direction, wherein
the plurality of first conductive layers are each continuously formed between the first insulating portions mutually adjacent in the third direction, and the plurality of first conductive layers contain a first material, and
the plurality of second conductive layers contain a second material different from the first material.

10. The semiconductor memory device according to claim 9, wherein
the semiconductor layer is integrally formed in the first direction.

11. The semiconductor memory device according to claim 9, wherein
at least two second insulating portions of the plurality of second insulating portions are disposed between the first insulating portions mutually adjacent in the third direction,
the at least two second insulating portions separate the plurality of second conductive layers in the third direction into three or more between the first insulating portions mutually adjacent in the third direction.

12. The semiconductor memory device according to claim 9, further comprising
a plurality of the semiconductor layers disposed in the second direction and the third direction, wherein
the plurality of semiconductor layers include:
a plurality of first semiconductor layers disposed at positions separated from the at least one second insulating portion between the first insulating portions mutually adjacent in the third direction; and
a plurality of second semiconductor layers disposed in the second direction to be in contact with the at least one second insulating portion between the first insulating portions mutually adjacent in the third direction.

13. The semiconductor memory device according to claim 9, wherein
one end portion in the first direction of at least one of the plurality of second portions is in contact with a first conductive layer closest to the plurality of second conductive layers among the plurality of first conductive layers.

14. The semiconductor memory device according to claim 9, wherein
a metal oxide film is disposed between the plurality of first conductive layers and the gate insulating layer, and
a distance between the plurality of first conductive layers and the semiconductor layer is greater than a distance between the plurality of second conductive layers and the semiconductor layer.

15. The semiconductor memory device according to claim 9, wherein
the first material contains tungsten or molybdenum, and the second material contains polysilicon.

16. The semiconductor memory device according to claim 15, wherein
the plurality of first conductive layers each include a first conductive film and a barrier metal film, the first conductive film contains tungsten or molybdenum, the barrier metal film is disposed to cover the first conductive film, and the barrier metal film is interposed between the first conductive film and the gate insulating layer,
the plurality of second conductive layers each include a second conductive film that contains polysilicon, and the second conductive film is not covered with a barrier metal film, and
a distance between the first conductive film and the semiconductor layer is greater than a distance between the second conductive film and the semiconductor layer.

17. The semiconductor memory device according to claim 9, wherein
the first material contains molybdenum, and the second material contains tungsten.

18. A semiconductor memory device comprising:
a plurality of first conductive layers disposed to be mutually separated in a first direction, the plurality of first conductive layers extending in a second direction intersecting with the first direction;
a second conductive layer disposed to be separated from the plurality of first conductive layers in the first direction, the second conductive layer extending in the second direction;
a semiconductor layer that extends in the first direction, the semiconductor layer being opposed to the plurality of first conductive layers and the second conductive layer;
a gate insulating layer disposed between the plurality of first conductive layers and the semiconductor layer and between the second conductive layer and the semiconductor layer;
a plurality of first insulating portions that extend in the first direction and the second direction in the plurality of first conductive layers and the second conductive layer, the plurality of first insulating portions separating the plurality of first conductive layers and the second conductive layer in a third direction intersecting with the first direction and the second direction; and
a plurality of second insulating portions that extend in the first direction and the second direction in the second conductive layer, at least one second insulating portion of the plurality of second insulating portions being disposed between first insulating portions of the plurality of first insulating portions mutually adjacent in the third direction, the at least one second insulating portion separating the second conductive layer in the third direction into two or more between the first insulating portions mutually adjacent in the third direction, wherein
the plurality of first conductive layers are each continuously formed between the first insulating portions mutually adjacent in the third direction, and the plurality of first conductive layers contain a first material,
the second conductive layer contains a second material different from the first material, and
one end portion in the first direction of at least one of the plurality of second portions is in contact with the first conductive layer closest to the second conductive layer among the plurality of first conductive layers.

19. The semiconductor memory device according to claim 18, wherein
respective one end portions of the plurality of second insulating portions terminate at positions closer to the second conductive layer than a surface of the first conductive layer closest to the second conductive layer, the surface being on a distal side to the second conductive layer.

20. The semiconductor memory device according to claim 18, wherein
at least two second insulating portions of the plurality of second insulating portions are disposed between the first insulating portions mutually adjacent in the third direction,
the at least two second insulating portions separate the second conductive layer in the third direction into three or more between the first insulating portions mutually adjacent in the third direction.
